(19) United States
(12) Patent Application Publication
(10) Pub. No.: US 2023/0231045 A1
(43) Pub. Date: Jul. 20, 2023

(54) SEMICONDUCTOR DEVICE, METHOD FOR MANUFACTURING SEMICONDUCTOR DEVICE, AND ELECTRONIC DEVICE

(71) Applicant: Fujitsu Limited, Kawasaki (JP)

(72) Inventors: Atsushi YAMADA, Hiratsuka (JP); Yuichi MINOURA, Machida (JP); Yusuke KUMAZAKI, Atsugi (JP)

(73) Assignee: Fujitsu Limited, Kawasaki (JP)

(21) Appl. No.: 18/049,153

(22) Filed: Oct. 24, 2022

(30) Foreign Application Priority Data
Jan. 17, 2022 (JP) 2022-005080

(51) Int. Cl. H01L 29/778; H01L 29/04; H01L 29/20; H01L 29/205; H01L 29/32; H01L 29/417; H01L 21/02; H01L 29/66

(52) U.S. Cl. CPC H01L 29/7786; H01L 29/045; H01L 29/2003; H01L 29/205; H01L 29/32; H01L 29/41766; H01L 21/02378; H01L 21/02458; H01L 21/0254; H01L 21/0262; H01L 29/66462

(57) ABSTRACT

A semiconductor device includes a channel layer configured to include a first nitride semiconductor containing gallium (Ga) and a first crystal dislocation density, and a barrier layer provided over a first surface side of the channel layer, and configured to include a second nitride semiconductor containing aluminum (Al) and a second crystal dislocation density, wherein the second crystal dislocation density is larger than the first crystal dislocation density.

### CROSS-REFERENCE TO RELATED APPLICATION

This application is based upon and claims the benefit of priority of the prior Japanese Patent Application No. 2022-5080, filed on Jan. 17, 2022, the entire contents of which are incorporated herein by reference.

### FIELD

Embodiments discussed herein are related to a semiconductor device, a method for manufacturing a semiconductor device, and an electronic device.

### BACKGROUND

A technique is known in which a high-electron-mobility transistor (HEMT) including a barrier layer (also referred to as a carrier channel layer or an electron channel layer) made of gallium nitride (GaN) and a barrier layer (also referred to as a carrier supply layer or an electron supply layer) made of indium aluminum nitride (InAlN), indium aluminum gallium nitride (InAlGaN), or the like is formed by using a substrate made of silicon carbide (SiC) or the like.

Regarding such a technique, there has been proposed a technique in which pits originating from dislocations or the like are formed by etching in regions of the carrier supply layer that are to overlap a source electrode and a drain electrode and the source electrode and the drain electrode are formed over the carrier supply layer to partially enter the pits. There has been also proposed a technique in which, in the above-mentioned formation, the pits are formed at a density of 5.0×10⁸/cm² or higher in the regions of the carrier supply layer that are to overlap the source electrode and the drain electrode.

There has been also proposed a technique in which multiple pit-shaped projections are formed in at least a source electrode out of the source electrode and a drain electrode formed over an electron supply layer, the projections entering the nitride semiconductor layer side and having a width that gradually becomes smaller toward a lower end portion.

Japanese Laid-open Patent Publication Nos. 2017-85006 and 2019-192698 are disclosed as related art.

### SUMMARY

According to an aspect of the embodiments, a semiconductor device includes a channel layer configured to include a first nitride semiconductor containing gallium (Ga) and a first crystal dislocation density, and a barrier layer provided over a first surface side of the channel layer, and configured to include a second nitride semiconductor containing aluminum (Al) and a second crystal dislocation density, wherein the second crystal dislocation density is larger than the first crystal dislocation density.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A and 1B are diagrams for explaining an example of a semiconductor device;

FIG. 2 is a diagram illustrating an example of a semiconductor device obtained by adopting pit assist etching;

FIGS. 3A and 3B are diagrams (part 1) for explaining an example of the pit assist etching;

FIGS. 4A and 4B are diagrams (part 2) for explaining the example of the pit assist etching;

FIGS. 5A and 5B are diagrams for explaining crystal dislocations formed in a nitride semiconductor laminate structure;

FIGS. 6A and 6B are diagrams illustrating a configuration example of the semiconductor device obtained by adopting the pit assist etching;

FIGS. 7A and 7B are diagrams for explaining a crystal dislocation density of a channel layer;

FIGS. 8A and 8B are diagrams for explaining an example of a semiconductor device according to the first embodiment;

FIG. 9 is a diagram for explaining a relationship between growth temperature and a crystal dislocation density of a barrier layer;

FIG. 10 is a diagram for explaining an example of a semiconductor device according to a second embodiment;

FIGS. 11A to 11C are diagrams (part 1) for explaining an example of a method for manufacturing the semiconductor device according to the second embodiment;

FIGS. 12A and 12B are diagrams (part 2) for explaining the example of the method of manufacturing the semiconductor device according to the second embodiment;

FIGS. 13A and 13B are diagrams (part 3) for explaining the example of the method for manufacturing the semiconductor device according to the second embodiment;

FIGS. 14A and 14B are diagrams (part 4) for explaining the example of the method for manufacturing the semiconductor device according to the second embodiment;

FIG. 15 is a diagram for explaining an example of a semiconductor device according to a third embodiment;

FIGS. 16A and 16B are diagrams for explaining an example of a method for manufacturing the semiconductor device according to the third embodiment;

FIG. 17 is a diagram for explaining an example of a semiconductor device according to a fourth embodiment;

FIG. 18 is a diagram for explaining an example of a semiconductor package according to a fifth embodiment;

FIG. 19 is a diagram for explaining an example of a power factor correction circuit according to a sixth embodiment;

FIG. 20 is a diagram for explaining an example of a power supply device according to a seventh embodiment; and

FIG. 21 is a diagram for explaining an example of an amplifier according to an eighth embodiment.

### DESCRIPTION OF EMBODIMENTS

A semiconductor device using a nitride semiconductor adopts, for example, a structure in which a barrier layer including a nitride semiconductor with a larger band gap than a nitride semiconductor of a channel layer is grown over the channel layer including the nitride semiconductor. A two dimensional electron gas (2DEG) is generated in a portion of the channel layer near a junction interface on the barrier layer side by spontaneous polarization of the barrier layer and piezoelectric polarization generated by distortion due to a difference in lattice constant between the barrier layer and the channel layer.

In the semiconductor device adopting such a structure, the band gap of the barrier layer is relatively large. Accordingly, a barrier between the barrier layer and each of the source electrode and the drain electrode provided over the barrier layer is high and contact resistance is high in some cases. When the contact resistance is high, the resistance of an electron transport path in the semiconductor device is high, and a high-performance semiconductor device may not be obtained. As one of techniques for reducing the contact resistance, the following technique has been proposed. A method in which pits are formed by etching in the barrier layer by originating from crystal dislocations in the barrier layer (so-called pit assist etching) is adopted and the source electrode and the drain electrode are partially formed in the formed pits. Partially forming the source electrode and the drain electrode in the pits reduces a distance between the 2DEG and each of the source electrode and the drain electrode and reduces the contact resistance.

By the way, using a channel layer having a low crystal dislocation density is effective for improvement of a performance of a semiconductor device such as reduction of a leakage current. A barrier layer grown over the channel layer having a low crystal dislocation density may have a low crystal dislocation density by reflecting the crystal dislocation density of the channel layer. When the pit assist etching as described above is adopted for the barrier layer having a low crystal dislocation density, the number of pits formed by etching by originating from the crystal dislocations is small, and the number of electrode portions formed in the pits is also small. Accordingly, there is a risk that the effect of reducing the contact resistance is not sufficiently obtained and a high-performance semiconductor device is not obtained.

A semiconductor device using a nitride semiconductor is being developed as a device with high withstand voltage and high output by utilizing characteristics such as a high saturated electron velocity and a wide band gap. A field-effect transistor (FET), for example, a HEMT has been reported many times as the semiconductor device using the nitride semiconductor.

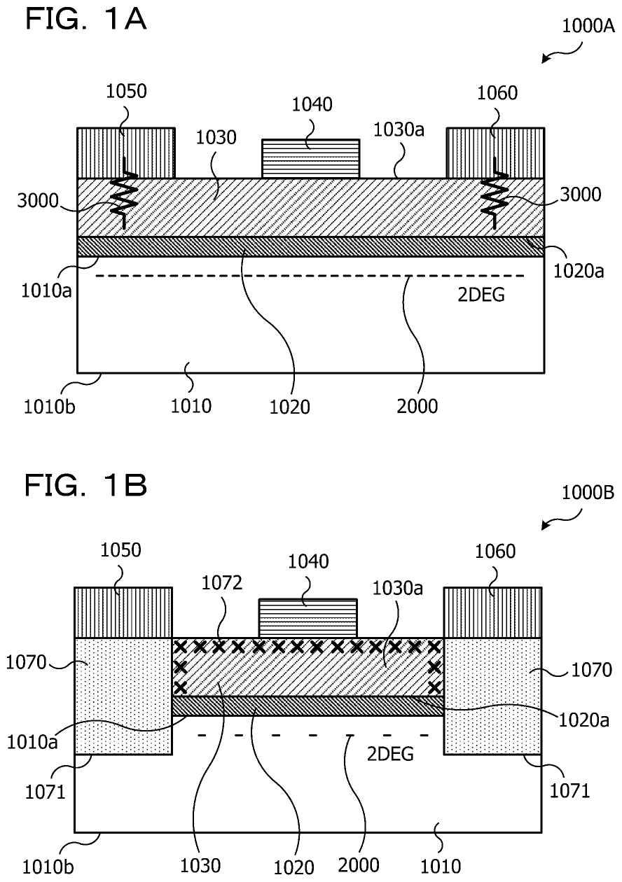

FIGS. 1A and 1B are diagrams for explaining an example of a semiconductor device. FIG. 1A schematically illustrates a main portion cross-sectional diagram of a first example of the semiconductor device. FIG. 1B schematically illustrates a main portion cross-sectional diagram of a second example of the semiconductor device.

The semiconductor device 1000A illustrated in FIG. 1A is an example of the HEMT. The semiconductor device 1000A includes a channel layer 1010, a spacer layer 1020, a barrier layer 1030, a gate electrode 1040, a source electrode 1050, and a drain electrode 1060.

The channel layer 1010 has a surface 1010a and a surface 1010b on the opposite side to the surface 1010a. For example, GaN is used for the channel layer 1010. The spacer layer 1020 is provided on the surface 1010a side that is one of the surface 1010a and the surface 1010b of the channel layer 1010. For example, aluminum nitride (AlN), AlGaN, or the like having a band gap larger than that of GaN is used for the spacer layer 1020. The barrier layer 1030 is provided on a surface 1020a side of the spacer layer 1020 opposite to the channel layer 1010 side. For example, AlN, AlGaN, InAlN, InAlGaN or the like having a band gap larger than that of GaN is used for the barrier layer 1030. The gate electrode 1040, the source electrode 1050, and the drain electrode 1060 are provided on a surface 1030a side of the barrier layer 1030 opposite to the spacer layer 1020 and channel layer 1010 side. A predetermined metal is used for each of the gate electrode 1040, the source electrode 1050, and the drain electrode 1060. The gate electrode 1040 is provided to function as a Schottky electrode. The source electrode 1050 and the drain electrode 1060 are located apart from each other with the gate electrode 1040 arranged between the source electrode 1050 and the drain electrode 1060, and are provided to function as ohmic electrodes.

In the semiconductor device 1000A, a 2DEG 2000 is generated in the channel layer 1010 by spontaneous polarization of the spacer layer 1020 and the barrier layer 1030 and piezoelectric polarization generated by distortion due to differences in lattice constants between each of the spacer layer 1020 and the barrier layer 1030 and the channel layer 1010. During an operation of the semiconductor device 1000A, predetermined voltage is supplied between the source electrode 1050 and the drain electrode 1060, and predetermined gate voltage is supplied to the gate electrode 1040. A channel through which electrons of carriers are transported is formed between the source electrode 1050 and the drain electrode 1060 in the channel layer 1010, and a transistor function of the semiconductor device 1000A is achieved.

When a nitride semiconductor with a high Al composition is used for the barrier layer 1030 in the semiconductor device 1000A as described above, strong spontaneous polarization of the barrier layer 1030 enables generation of a high-concentration 2DEG 2000. Meanwhile, when the Al composition of the barrier layer 1030 is increased, a barrier between the barrier layer 1030 and each of the source electrode 1050 and the drain electrode 1060 becomes higher due to a large band gap attributable to the high Al composition. When the barrier becomes higher, contact resistance 3000 between the barrier layer 1030 and each of the source electrode 1050 and the drain electrode 1060 increases, and good ohmic contact with the source electrode 1050 and the drain electrode 1060 may not be achieved. When the contact resistance 3000 increases and good ohmic contact is not achieved, the resistance of the electron transport path formed between the source electrode 1050 and the drain electrode 1060 via the channel layer 1010 increases as a whole and the on-resistance increases. Here, there is a risk that the semiconductor device 1000A with sufficient output characteristics is not obtained.

A technique of forming a regrowth layer with low resistance is proposed as an example of a technique for reducing the contact resistance 3000.

A semiconductor device 1000B illustrated in FIG. 1B is an example of the HEMT adopting the technique of forming a regrowth layer 1070 with a low resistance. The semiconductor device 1000B has a configuration in which a regrowth layer 1070 that penetrates the barrier layer 1030 and the spacer layer 1020 and that reaches the channel layer 1010 is provided and the source electrode 1050 and the drain electrode 1060 are coupled to the regrowth layer 1070. The semiconductor device 1000B is different from the semiconductor device 1000A (FIG. 1A) described above in that the semiconductor device 1000B has such a configuration.

In formation of the semiconductor device 1000B, first, a nitride semiconductor laminate structure is formed by growing the channel layer 1010, the spacer layer 1020, and the barrier layer 1030, and recesses 1071 reaching, for example, the channel layer 1010 are formed in regions where the source electrode 1050 and the drain electrode 1060 are to be formed. Then, the regrowth layer 1070 is formed in the formed recesses 1071. For example, the regrowth layer 1070 is formed by growing GaN (n-GaN) that is doped while using Si (silicon) or the like as an n-type impurity. The source electrode 1050 and the drain electrode 1060 are formed over the formed regrowth layer 1070, the gate electrode 1040 is formed on the surface 1030a side of the barrier layer 1030, and the semiconductor device 1000B as illustrated in FIG. 1B is obtained.

In the semiconductor device 1000B, the regrowth layer 1070 with low resistance reduces the contact resistance of the source electrode 1050 and the drain electrode 1060, and reduction in on-resistance is expected. However, when such a technique of forming the regrowth layer 1070 is adopted, the man-hour increases due to the formation of the regrowth layer 1070. In the formation of the regrowth layer 1070, damage 1072 such as a defect may occur in the barrier layer 1030, for example, in a surface layer portion thereof. For example, assume a case where an In-based nitride semiconductor such as InAlGaN is used for the barrier layer 1030. In this case, if the regrowth layer 1070 is formed at temperature higher than the growth temperature of the In-based nitride semiconductor, there is a possibility that In in the barrier layer 1030 desorbs and damage 1072 such as a defect occurs. The damage 1072 occurring in the barrier layer 1030 may cause a decrease of 2DEG 2000, an increase in on-resistance, and the like in the semiconductor device 1000B.

As another example of the technique for reducing the contact resistance 3000, there has been proposed a technique of adopting a method of forming pits by etching in the barrier layer 1030 by utilizing crystal dislocations in the barrier layer 1030 (so-called pit assist etching).

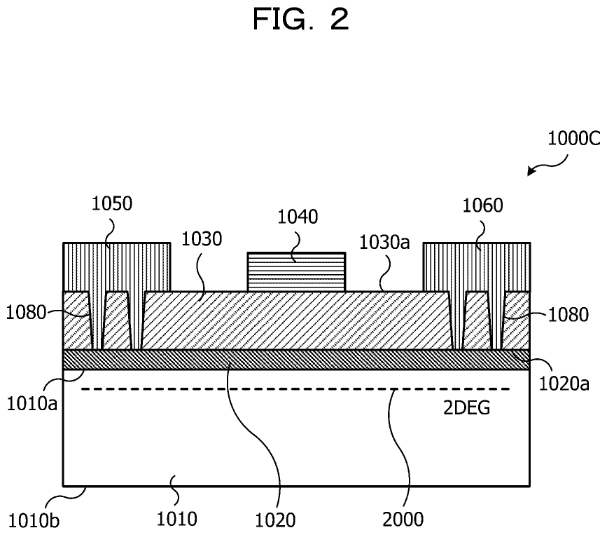

FIG. 2 is a diagram illustrating an example of a semiconductor device obtained by adopting the pit assist etching. FIG. 2 schematically illustrates a main portion cross-sectional diagram of the example of the semiconductor device. The semiconductor device 1000C illustrated in FIG. 2 is an example of the HEMT obtained by adopting the pit assist etching. The semiconductor device 1000C has a configuration in which the source electrode 1050 and the drain electrode 1060 are partially formed in pits 1080 formed in the barrier layer 1030. The semiconductor device 1000C is different from the semiconductor device 1000A (FIG. 1A) described above in that the semiconductor device 1000C has such a configuration.

In formation of the semiconductor device 1000C, the pits 1080 are formed in the barrier layer 1030 by utilizing the crystal dislocations therein, and the source electrode 1050 and the drain electrode 1060 are partially formed in the formed pits 1080. For example, the pits 1080 are formed to penetrate the barrier layer 1030 and reach the spacer layer 1020. Alternatively, the pits 1080 may end in the middle of the barrier layer 1030 in the thickness direction. Each of the pits 1080 is formed such that a distance between a lower end thereof and the 2DEG 2000 is equal to or smaller than a distance at which electron tunneling is possible.

In the semiconductor device 1000C, forming the pits 1080 in the barrier layer 1030 and partially forming the source electrode 1050 and the drain electrode 1060 in the pits 1080 reduces the distance between the 2DEG 2000 and each of the source electrode 1050 and the drain electrode 1060. Accordingly, the contact resistance is reduced and the on-resistance is reduced.

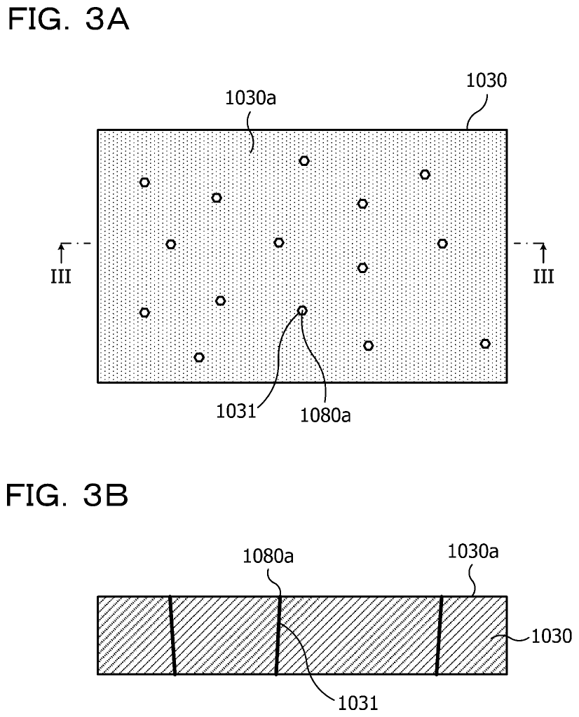

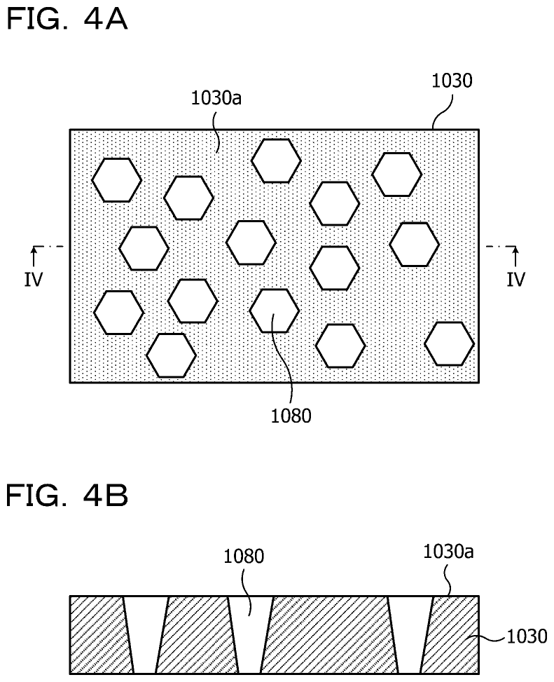

The pit assist etching is described. FIGS. 3A to 4B are diagrams for explaining an example of the pit assist etching. FIG. 3A schematically illustrates a plan view of a main portion of the barrier layer before the etching. FIG. 3B schematically illustrates a cross-sectional diagram taken along the line III-III in FIG. 3A. FIG. 4A schematically illustrates a plan view of a main portion of the barrier layer after the etching. FIG. 4B schematically illustrates a cross-sectional diagram taken along the line IV-IV in FIG. 4A.

In the formation of the semiconductor device 1000C, crystal dislocations 1031 as illustrated in FIGS. 3A and 3B are formed in the barrier layer 1030 grown on the surface 1010a side of the channel layer 1010 with the spacer layer 1020 interposed between the channel layer 1010 and the spacer layer 1030. For example, the crystal dislocations 1031 in the barrier layer 1030 are formed by reflecting crystal dislocations in the spacer layer 1020 under the barrier layer 1030. Note that the crystal dislocations in the spacer layer 1020 are formed by reflecting crystal dislocations in the channel layer 1010 under the spacer layer 1020. Pits 1080a (small pits) having a relatively small size in a plan view as illustrated in FIG. 3A are formed at the positions of the crystal dislocations 1031 over the surface 1030a of the barrier layer 1030 in which the crystal dislocations 1031 are formed. Relatively small pits 1080a having a hexagonal shape in the plan view are formed in the surface 1030a (c-surface, (0001) surface, III-polar surface) of the barrier layer 1030 using a nitride semiconductor with a wurtzite structure.

Wet etching or dry etching is performed on the barrier layer 1030 in which such pits 1080a are formed. The etching originating from the crystal dislocations 1031 (pits 1080a at the positions of the crystal dislocations 1031) in the barrier layer 1030 thereby preferentially proceeds, and the pits 1080 (large pits) having a relatively large size and a hexagonal shape in the plan view as illustrated in FIGS. 4A and 4B are formed. When a method in which etching proceeds isotropically is used for such etching formation of the pits 1080, each of the pits 1080 is formed in a tapered shape in which the width of the pit 1080 is large on the surface 1030a side of the barrier layer 1030 and becomes smaller toward the inside of the barrier layer 1030. This method is the so-called pit assist etching.

In the formation of the semiconductor device 1000C, the pits 1080 are formed by the pit assist etching as described above in the regions of the barrier layer 1030 where the source electrode 1050 and the drain electrode 1060 are to be formed. The source electrode 1050 and the drain electrode 1060 are formed on the surface 1030a side of the barrier layer 1030 in which the pits 1080 are formed. The source electrode 1050 and the drain electrode 1060 are formed to partially enter the pits 1080 in the barrier layer 1030. The distance between the 2DEG 2000 and each of the source electrode 1050 and the drain electrode 1060 is thereby reduced, and the contact resistance is reduced.

In the semiconductor device 1000C, the larger the number of the pits 1080 in the barrier layer 1030 formed such that the source electrode 1050 and the drain electrode 1060 partially enter the pits 1080 is, the higher the obtained contact resistance reduction effect is. The number of the pits 1080 in the barrier layer 1030 that affects the contact resistance reduction effect as described above depends on the number of the crystal dislocations 1031 included in the barrier layer 1030 grown on the surface 1010a side of the channel layer 1010 with the spacer layer 1020 interposed between the channel layer 1010 and the barrier layer 1030.

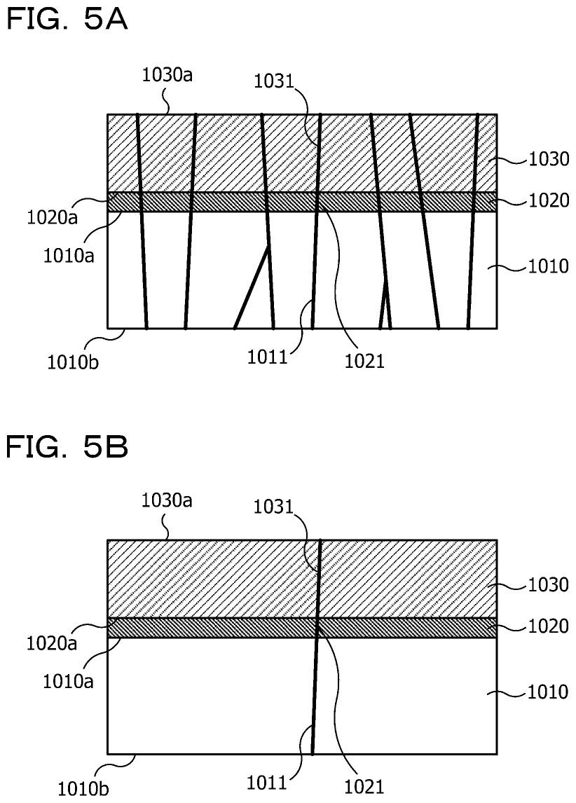

FIGS. 5A and 5B are diagrams for explaining crystal dislocations formed in a nitride semiconductor laminate structure. FIG. 5A schematically illustrates a main portion cross-sectional diagram of a first example of the nitride semiconductor laminate structure in which crystal dislocations are formed. FIG. 5B schematically illustrates a main portion cross-sectional diagram of a second example of the nitride semiconductor laminate structure in which crystal dislocations are formed.

As described above, the crystal dislocations 1031 in the barrier layer 1030 are formed by reflecting, for example, the crystal dislocations 1021 in the spacer layer 1020 under the barrier layer 1030, and the crystal dislocations 1021 in the spacer layer 1020 are formed by reflecting the crystal dislocations 1011 in the channel layer 1010 under the spacer layer 1020.

Accordingly, as illustrated in FIG. 5A, when the density of the crystal dislocations 1011 in the channel layer 1010 is relatively high, the crystal dislocations 1021 are formed in the spacer layer 1020 at a relatively high density and the crystal dislocations 1031 are also formed in the barrier layer 1030 at a relatively high density, by reflecting the relatively high density of the crystal dislocations 1011. Meanwhile, as illustrated in FIG. 5B, when the density of the crystal dislocations 1011 in the channel layer 1010 is relatively low, the crystal dislocations 1021 are formed in the spacer layer 1020 at a relatively low density and the crystal dislocations 1031 are also formed in the barrier layer 1030 at a relatively low density, by reflecting the relatively low density of the crystal dislocations 1011.

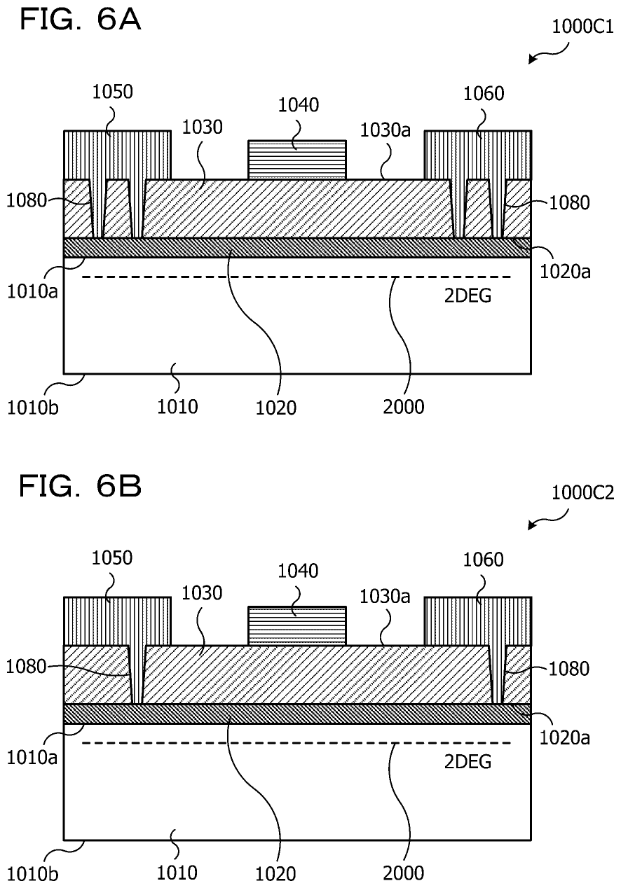

The cases where the pit assist etching is performed on the barrier layers 1030 as illustrated in FIGS. 5A and 5B, respectively, and the source electrode 1050 and the drain electrode 1060 are formed are considered. In these cases, for example, a semiconductor device 1000C1 and a semiconductor device 1000C2 as illustrated in FIGS. 6A and 6B, respectively, are obtained.

FIGS. 6A and 6B are diagrams illustrating configuration examples of the semiconductor device obtained by adopting the pit assist etching. FIG. 6A schematically illustrates a main portion cross-sectional diagram of an example of the semiconductor device in the case where a barrier layer with a relatively high crystal dislocation density is used. FIG. 6B schematically illustrates a main portion cross-sectional diagram of an example of the semiconductor device in the case where a barrier layer with a relatively low crystal dislocation density is used.

When the density of the crystal dislocations 1011 in the channel layer 1010 is relatively high and the density of the crystal dislocations 1031 in the barrier layer 1030 grown on the surface 1010a side of the channel layer 1010 with the spacer layer 1020 interposed between the channel layer 1010 and the barrier layer 1030 is relatively high as illustrated in FIG. 5A described above, the semiconductor device 1000C1 as illustrated in FIG. 6A is obtained. Since the density of the crystal dislocations 1031 in the barrier layer 1030 is relatively high in the semiconductor device 1000C1, when the pit assist etching is performed, the number of the pits 1080 formed to originate from the crystal dislocations 1031 is relatively large. Accordingly, the number of electrode portions of the source electrode 1050 and the drain electrode 1060 formed in the pits 1080 is also relatively large, and the sufficient contact resistance reduction effect is obtained.

Meanwhile, when the density of the crystal dislocations 1011 in the channel layer 1010 is relatively low and the density of the crystal dislocations 1031 in the barrier layer 1030 grown on the surface 1010a side of the channel layer 1010 with the spacer layer 1020 interposed between the channel layer 1010 and the spacer layer 1030 is relatively low as illustrated in FIG. 5B described above, the semiconductor device 1000C2 as illustrated in FIG. 6B is obtained. Since the density of the crystal dislocations 1031 in the barrier layer 1030 is relatively low in the semiconductor device 1000C2, when the pit assist etching is performed, the number of the pits 1080 formed to originate from the crystal dislocations 1031 is relatively small. Accordingly, the number of electrode portions of the source electrode 1050 and the drain electrode 1060 formed in the pits 1080 is also relatively small, and the sufficient contact resistance reduction effect may not be obtained.

As described above, in the semiconductor device 1000C1 illustrated in FIG. 6A, the barrier layer 1030 (FIG. 5A) with a relatively high density of the crystal dislocations 1031 is used. When the pit assist etching is performed in this case, a relatively large number of pits 1080 are formed in the barrier layer 1030. As a result, the number of electrode portions of the source electrode 1050 and the drain electrode 1060 formed in the pits 1080 is relatively large, and the sufficient contact resistance reduction effect may be obtained. However, in the semiconductor device 1000C1, the channel layer 1010 (FIG. 5A) with a relatively high density of the crystal dislocations 1011 is used as an underlayer of the barrier layer 1030 with a relatively high density of the crystal dislocations 1031. Such a channel layer 1010 is likely to cause scattering or trapping of electrons, current collapse, a leakage current, or the like.

From the viewpoint of reducing a leakage current and the like, the density of the crystal dislocations 1011 in the channel layer 1010 is preferably low. However, when the channel layer 1010 (FIG. 5B) with a relatively low density of the crystal dislocations 1011 is used, the density of the crystal dislocations 1031 in the barrier layer 1030 grown on the surface 1010a side of the channel layer 1010 is relatively low. When the pit assist etching is performed on the barrier layer 1030 (FIG. 5B) with a relatively low density of the crystal dislocations 1031, the number of the pits 1080 formed to originate from the crystal dislocations 1031 is relatively small due to the relatively low density of the crystal dislocations 1031. As a result, there may be formed the semiconductor device 1000C2 as illustrated in FIG. 6B, for example, the semiconductor device 1000C2 in which the number of the electrode portions of the source electrode 1050 and the drain electrode 1060 formed in the pits 1080 is relatively small and the sufficient contact resistance reduction effect is not obtained.

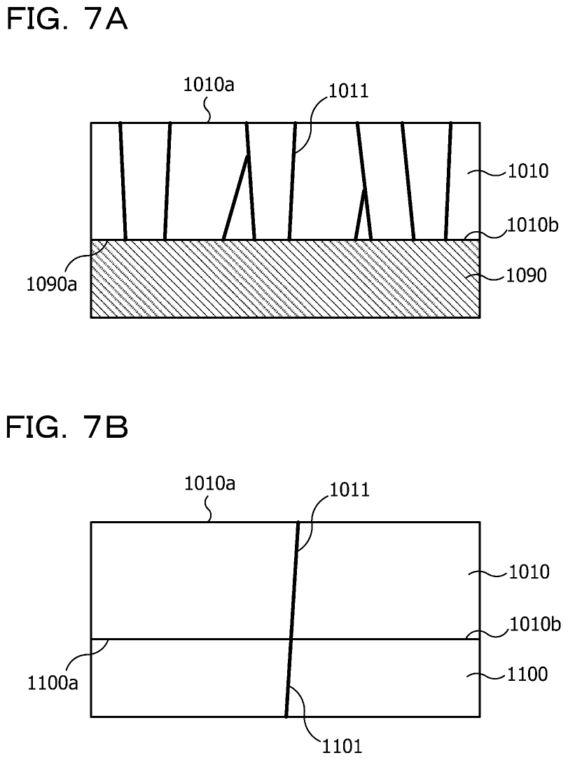

Variations in the density of the crystal dislocations 1011 depending on variations in an underlying substrate of the channel layer 1010 is further described. FIGS. 7A and 7B are diagrams for explaining the crystal dislocation density of the channel layer. FIG. 7A schematically illustrates a main portion cross-sectional diagram of an example of a laminate structure in which the channel layer is grown over a heterogenous substrate. FIG. 7B schematically illustrates a main portion cross-sectional diagram of an example of a laminate structure in which the channel layer is grown over a homogenous substrate.

For example, when GaN is used for the channel layer 1010, a substrate made of a material different from GaN of the channel layer 1010, such as a SiC substrate, a Si substrate, or a sapphire substrate may be used as the underlying substrate for the growth of the channel layer 1010, for example, the underlying substrate arranged on the surface 1010b side opposite to the surface 1010a side on which the spacer layer 1020 and the barrier layer 1030 are to be grown. For example, as illustrated in FIG. 7A, the channel layer 1010 made of GaN is grown on a surface 1090a side of a SiC substrate 1090. In this case, lattice mismatch is likely to occur between the SiC substrate 1090 and the channel layer 1010 made of GaN and grown on the surface 1090a side of the SiC substrate 1090. Accordingly, the crystal dislocations 1011 due to the lattice mismatch with the SiC substrate 1090 are likely to occur in the channel layer 1010 made of GaN. As an example, a relatively large number of crystal dislocations 1011 whose density is in a range from about 1×10⁸/cm² to about 1×10¹²/cm² are formed in the channel layer 1010 made of GaN and grown on the surface 1090a side of the SiC substrate 1090.

Causing the channel layer 1010 to include many crystal dislocations 1011 is effective in increasing the number of the crystal dislocations 1031 in the barrier layer 1030 grown on the surface 1010a side (FIG. 5A) of the channel layer 1010 and increasing the number of the pits 1080 formed by the pit assist etching (FIG. 6A). Increasing the number of the pits 1080 may increase the number of the electrode portions of the source electrode 1050 and the drain electrode 1060 entering the pits 1080 and reduce the contact resistance. However, the many crystal dislocations 1011 included in the channel layer 1010 may cause scattering or trapping of electrons, current collapse, a leakage current, or the like.

In this regard, for example, a technique is known in which the channel layer 1010 made of GaN is grown on a surface 1100a side of a substrate made of the same material as the channel layer 1010, for example, a GaN substrate 1100 as illustrated in FIG. 7B. In recent years, preparing a GaN substrate 1100 with a sufficiently low density of crystal dislocations 1101 has become possible. The channel layer 1010 made of GaN easily lattice-matches with the GaN substrate 1100 with few crystal dislocations. Accordingly, as illustrated in FIG. 7B, when the GaN substrate 1100 with a low density of the crystal dislocations 1101 is used as the underlying substrate for growth that is arranged on the surface 1010b side of the channel layer 1010 made of GaN, the crystal dislocations 1011 formed in the channel layer 1010 made of GaN and grown on the surface 1100a side of the GaN substrate 1100 are suppressed. As an example, the density of the crystal dislocations 1011 in the channel layer 1010 made of GaN and grown on the surface 1100a side of the GaN substrate 1100 is suppressed to a range from about 1×10³/cm² to about 1×10⁶/cm². This is a very low value as compared with the density of the crystal dislocations 1011 in the channel layer 1010 made of GaN and grown on the surface 1090a side of the SiC substrate 1090 described above.

Suppressing the crystal dislocations 1011 in the channel layer 1010 enables suppression of scattering or trapping of electrons, current collapse, a leakage current, or the like. However, when such a channel layer 1010 with a low density of the crystal dislocations 1011 is used, the density of the crystal dislocations 1031 in the barrier layer 1030 may also be low in the nitride semiconductor growth technique of the related art as described above (FIG. 5B). As a result, the number of the formed pits 1080 is reduced and the number of the electrode portions of the source electrode 1050 and the drain electrode 1060 entering the pits 1080 is also reduced. The case where the sufficient contact resistance reduction effect is not obtained may thus occur (FIG. 6B).

As an example, assume that the plane size of each of the source electrode 1050 and the drain electrode 1060 is 100 μm². In this case, in the nitride semiconductor growth technique of the related art, the number of the crystal dislocations 1031 is in a range from about 10⁴ to about 10⁸ in the region of the barrier layer 1030 where the source electrode 1050 or the drain electrode 1060 is formed, the barrier layer 1030 grown on the surface 1090a side of the SiC substrate 1090 with the channel layer 1010 made of GaN interposed between the SiC substrate 1090 and the barrier layer 1030. Meanwhile, in the nitride semiconductor growth technique of the related art, the number of the crystal dislocations 1031 is in a range from about 10⁻¹ to about 10² in the region of the barrier layer 1030 where the source electrode 1050 or the drain electrode 1060 is formed, the barrier layer 1030 grown on the surface 1100a side of the GaN substrate 1100 with the channel layer 1010 made of GaN interposed between the GaN substrate 1100 and the barrier layer 1030. Accordingly, when the channel layer 1010 made of GaN is grown on the surface 1100a side of the GaN substrate 1100, the number of the pits 1080 formed in the barrier layer 1030 is small. The number of the portions of the source electrode 1050 and the drain electrode 1060 that enter the pits 1080 is thus also small, and the case where the sufficient contact resistance reduction effect is not obtained may occur.

As described above, suppressing the density of the crystal dislocations 1011 in the channel layer 1010 to a low level to reduce the leakage current or the like increases the possibility of occurrence of the situation where the sufficient contact resistance reduction effect is not obtained due to a small number of the pits 1080 in the barrier layer 1030. Growing the channel layer 1010 over the underlying substrate made of the same material as that of the channel layer 1010 to form the channel layer 1010 with a low density of the crystal dislocations 1011 further increases the possibility of occurrence of the situation where the sufficient contact resistance reduction effect is not obtained due to a small number of the pits 1080 in the barrier layer 1030.

In view of the points described above, configurations as described in the following embodiments are adopted to achieve a high-performance semiconductor device that has a low contact resistance and a low on-resistance and in which a leakage current or the like may be suppressed.

### First Embodiment

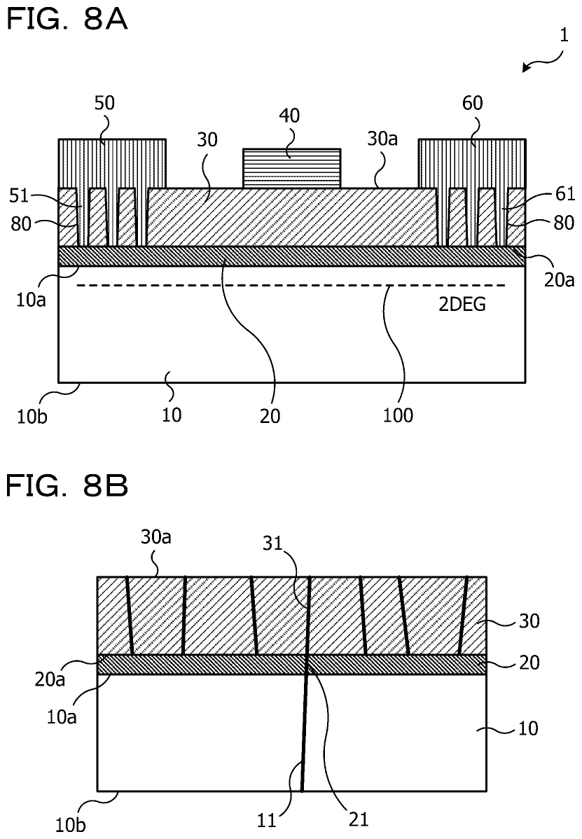

FIGS. 8A and 8B are diagrams for explaining an example of a semiconductor device according to a first embodiment. FIG. 8A schematically illustrates a main portion cross-sectional diagram of the example of the semiconductor device. FIG. 8B schematically illustrates a main portion cross-sectional diagram of an example of a nitride semiconductor laminate structure included in the semiconductor device.

The semiconductor device 1 illustrated in FIG. 8A is an example of the HEMT. The semiconductor device 1 includes a channel layer 10, a spacer layer 20, a barrier layer 30, a gate electrode 40, a source electrode 50, and a drain electrode 60.

The channel layer 10 has a surface (also referred to as a first surface) 10a and a surface (also referred to as a second surface) 10b on the opposite side to the surface 10a. The channel layer 10 includes a nitride semiconductor (also referred to as a first nitride semiconductor) containing Ga. For example, GaN is used for the channel layer 10. Although not illustrated, the channel layer 10 is provided over a predetermined underlying substrate arranged on the surface 10b side of the channel layer 10. For example, a GaN substrate is used as the underlying substrate. Alternatively, a SiC substrate, a Si substrate, a sapphire substrate, or the like or any of such substrates over which a nucleation layer is provided may be used as the underlying substrate.

The spacer layer 20 is provided on the surface 10a side that is one of the surface 10a and the surface 10b of the channel layer 10. The surface 10a of the channel layer 10 is, for example, a (0001) surface (c-surface, III-polar surface). The surface 10b of the channel layer 10 on the opposite side to the surface 10a is a (000-1) surface (N-polar surface). The spacer layer 20 includes a nitride semiconductor having a band gap larger than that of the nitride semiconductor included in the channel layer 10. The spacer layer 20 includes a nitride semiconductor containing Al (also referred to as a fifth nitride semiconductor). For example, AlN, AlGaN or the like having a band gap larger than that of GaN is used for the spacer layer 20.

The barrier layer 30 is provided on a surface 20a side of the spacer layer 20 opposite to the channel layer 10 side. The surface 20a of the spacer layer 20 is, for example, a (0001) surface (c-surface, III-polar surface). The barrier layer 30 includes a nitride semiconductor having a band gap larger than that of the nitride semiconductor included in the channel layer 10. The barrier layer 30 includes a nitride semiconductor (also referred to as a second nitride semiconductor) containing Al. For example, AlN, AlGaN, InAlN, InAlGaN, or the like having a band gap larger than that of GaN is used for the barrier layer 30.

In the semiconductor device 1, a 2DEG 100 is generated in the channel layer 10 by spontaneous polarization of the spacer layer 20 and the barrier layer 30 and piezoelectric polarization generated by distortion due to differences in lattice constants between each of the spacer layer 20 and the barrier layer 30 and the channel layer 10.

The gate electrode 40, the source electrode 50, and the drain electrode 60 are provided on a surface 30a side of the barrier layer 30 opposite to the spacer layer 20 and channel layer 10 side. The surface 30a of the barrier layer 30 is, for example, a (0001) surface (c-surface, III-polar surface). A predetermined metal is used for each of the gate electrode 40, the source electrode 50, and the drain electrode 60. The gate electrode 40 is provided to function as a Schottky electrode. The source electrode 50 and the drain electrode 60 are located apart from each other with the gate electrode 40 arranged between the source electrode 50 and the drain electrode 60, and are provided to function as ohmic electrodes. The source electrode 50 and the drain electrode 60 are also referred to as ohmic electrodes or simply as electrodes.

In the barrier layer 30 of the semiconductor device 1, multiple pits 80 are provided in each of a region where the source electrode 50 is formed and a region where the drain electrode 60 is formed. The source electrode 50 is partially provided in the multiple pits 80 in the region of the barrier layer 30 where the source electrode 50 is formed. The source electrode 50 includes multiple protrusions 51 (also referred to as electrode portions) extending into the barrier layer 30. Portions of the source electrode 50 entering the multiple pits 80 in the barrier layer 30 correspond to the multiple protrusions 51.

The drain electrode 60 is partially provided in the multiple pits 80 in the region of the barrier layer 30 where the drain electrode 60 is formed. The drain electrode 60 includes multiple protrusions 61 (also referred to as electrode portions) extending into the barrier layer 30. Portions of the drain electrode 60 entering the multiple pits 80 in the barrier layer 30 correspond to the multiple protrusions 61.

For example, the protrusions 51 of the source electrode 50, the protrusions 61 of the drain electrode 60, and the pits 80 in the barrier layer 30 in which the protrusions 51 and 61 are provided are formed to penetrate the barrier layer 30 and reach the spacer layer 20. Alternatively, the protrusions 51, the protrusions 61, and the pits 80 may end in the middle of the barrier layer 30 in the thickness direction. Each of the protrusions 51, the protrusions 61, and the pits 80 is formed such that the distance between a lower end thereof and the 2DEG 100 is equal to or smaller than a distance at which electron tunneling is possible.

In the operation of the semiconductor device 1, predetermined voltage is supplied between the source electrode 50 and the drain electrode 60, and predetermined gate voltage is supplied to the gate electrode 40. A channel through which electrons of carriers are transported is formed between the source electrode 50 and the drain electrode 60 in the channel layer 10, and a transistor function of the semiconductor device 1 is achieved.

As illustrated in FIG. 8B, the channel layer 10, the spacer layer 20, and the barrier layer 30 in the nitride semiconductor laminate structure of the semiconductor device 1 include a group of crystal dislocations 11, a group of crystal dislocations 21, and a group of crystal dislocations 31, respectively. As illustrated in FIG. 8B, the channel layer 10 includes a relatively small number of crystal dislocations 11 at a low density. As illustrated in FIG. 8B, the spacer layer 20 includes a relatively small number of crystal dislocations 21 at a low density, by reflecting the density of the crystal dislocations 11 in the channel layer 10 under the spacer layer 20. As illustrated in FIG. 8B, the barrier layer 30 includes a relatively large number of crystal dislocations 31 at a high density. The density of the crystal dislocations 11 (also referred to as a crystal dislocation density (first crystal dislocation density)) in the channel layer 10 and the density of the crystal dislocations 21 (also referred to as a crystal dislocation density (third crystal dislocation density)) in the spacer layer 20 are lower than the density of the crystal dislocations 31 (also referred to as a crystal dislocation density (second crystal dislocation density)) in the barrier layer 30.

For example, the channel layer 10, the spacer layer 20, and the barrier layer 30 are grown by using a metal organic chemical vapor deposition (MOCVD) or metal organic vapor phase epitaxy (MOVPE) method or a molecular beam epitaxy (MBE) method. As described later, a growth condition of the barrier layer 30 is adjusted with respect to a growth condition of the channel layer 10 and the spacer layer 20 to grow the barrier layer 30 with a higher crystal dislocation density than those of the channel layer 10 and the spacer layer 20.

In the manufacturing of the semiconductor device 1, the pit assist etching is performed on regions of the barrier layer 30 where the source electrode 50 and the drain electrode 60 are to be formed, the barrier layer 30 grown as described above and including the crystal dislocations 31 at a relatively high density. The pits 80 are formed by the pit assist etching to originate from the crystal dislocations 31 in the barrier layer 30, according to the example as illustrated in FIGS. 3A, 3B, 4A, and 4B described above. The source electrode 50 and the drain electrode 60 are formed in the regions of the barrier layer 30 where the pits 80 are formed by etching. The source electrode 50 and the drain electrode 60 are formed to partially enter the pits 80 in the barrier layer 30. The source electrode 50 including the protrusions 51 provided in the pits 80 in the barrier layer 30 and the drain electrode 60 including the protrusions 61 provided in the pits 80 in the barrier layer 30 are thereby formed.

In the semiconductor device 1 having the above-mentioned configuration, the density of the crystal dislocations 31 in the barrier layer 30 is higher than the density of the crystal dislocations 11 in the channel layer 10 and the density of the crystal dislocations 21 in the spacer layer 20. The pit assist etching is performed on the barrier layer 30 including the crystal dislocations 31 at a relatively high density. Accordingly, the case where the number of the pits 80 formed by etching in the barrier layer 30 is small depending on a relatively low density of the crystal dislocations 11 in the channel layer 10 and a relatively low density of the crystal dislocations 21 in the spacer layer 20 is suppressed. Suppressing the case where the number of the pits 80 in the barrier layer 30 is small suppresses the case where the number of protrusions 51 of the source electrode 50 formed in the pits 80 and the number of protrusions 61 of the drain electrode 60 formed in the pits 80 are small. This reduces the contact resistance of the source electrode 50 and the drain electrode 60, and suppresses the case where the contact resistance reduction effect decreases due to a small number of the protrusions 51 and the protrusions 61 in the source electrode 50 and the drain electrode 60 (pits 80 in the barrier layer 30). In the semiconductor device 1, reducing the contact resistance of the source electrode 50 and the drain electrode 60 suppresses an increase in the resistance of the electron transport path formed between the source electrode 50 and the drain electrode 60 via the channel layer 10 and an increase in the on-resistance.

In the semiconductor device 1, the density of the crystal dislocations 11 in the channel layer 10 is lower than the density of the crystal dislocations 31 in the barrier layer 30. In the semiconductor device 1, using the channel layer 10 with a relatively low density of the crystal dislocations 11 suppresses scattering or trapping of electrons, current collapse, a leakage current, or the like.

According to the above-mentioned configuration, there is achieved the high-performance semiconductor device 1 that has a low contact resistance and a low on-resistance and in which a leakage current or the like may be suppressed.

The barrier layer 30 having a higher crystal dislocation density than those of the channel layer 10 and the spacer layer 20 is obtained by adjusting the growth condition of the barrier layer 30 with respect to the growth condition of the channel layer 10 and the spacer layer 20.

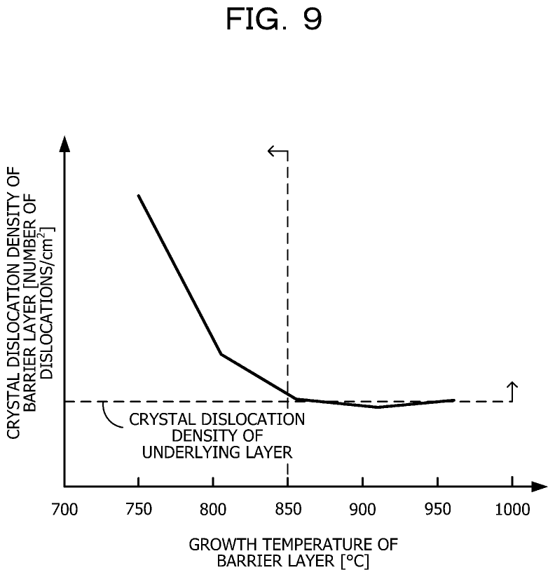

FIG. 9 is a diagram for explaining a relationship between growth temperature and the crystal dislocation density of the barrier layer. The horizontal axis of FIG. 9 represents the growth temperature [° C.] of the barrier layer 30 and the vertical axis of FIG. 9 represents the density [number/cm²] of the crystal dislocations 31 in the barrier layer 30.

As illustrated in FIG. 9, when the barrier layer 30 is grown under a growth condition of 850° C. or lower in a nitrogen atmosphere, the density of the crystal dislocations 31 in the barrier layer 30 is higher than that in the case where the barrier layer 30 is grown under a growth condition of temperature higher than 850° C.

For example, the channel layer 10 and the spacer layer 20 (underlying layer) grown on the surface 10a side of the channel layer 10 are grown under a growth condition where the densities of the crystal dislocations 11 and the crystal dislocations 21 respectively in the channel layer 10 and the spacer layer 20 become about the same as the density of the crystal dislocations 31 in the case where the barrier layer 30 is grown at temperature higher than 850° C. On the surface 20a side of the spacer layer 20 grown under the aforementioned growth condition, the barrier layer 30 is grown under the growth condition of 850° C. or lower in the nitrogen atmosphere. This enables growth of the barrier layer 30 including the crystal dislocations 31 at a higher density than the density of the crystal dislocations in the underlying layer in the growth of the barrier layer 30, for example, at a higher density than the density of the crystal dislocations 21 in the spacer layer 20 grown on the surface 10a side of the channel layer 10 in this example.

As described above, the barrier layer 30 having a higher crystal dislocation density than those of the channel layer 10 and the spacer layer 20 may be obtained by adjusting the atmosphere and the growth temperature in the growth of the barrier layer 30 with respect to the growth condition in the growth of the channel layer 10 and the spacer layer 20.

As an example, the channel layer 10 and the spacer layer 20 are grown under a growth condition where the densities of the crystal dislocations 11 and the crystal dislocations 21 respectively in the channel layer 10 and the spacer layer 20 become 1×10⁷/cm² or less, and the barrier layer 30 is grown under a growth condition where the density of the crystal dislocations 31 becomes 1×10⁸/cm² or more. When the barrier layer 30 is grown under the growth condition of 850° C. or lower in the nitrogen atmosphere, the density of the crystal dislocations 31 in the barrier layer 30 may be 1×10⁸/cm² or more.

Providing the spacer layer 20 made of AIN or AlGaN as in the semiconductor device 1 described above may suppress an effect of alloy scattering from the barrier layer 30 and reduce the on-resistance. However, the barrier layer 30 may be directly joined to the surface 10a side of the channel layer 10 without the provision of the spacer layer 20. In this case, the 2DEG 100 is generated in a portion of the channel layer 10 near a junction interface with the barrier layer 30.

For example, when no spacer layer 20 is provided, the channel layer 10 (underlying layer) is grown under a growth condition where the density of the crystal dislocations 11 in the channel layer 10 becomes about the same as the density of the crystal dislocations 31 in the case where the barrier layer 30 is grown at temperature higher than 850° C. On the surface 10a side of the channel layer 10 grown under such a growth condition, the barrier layer 30 is grown under the growth condition of 850° C. or lower in the nitrogen atmosphere. The barrier layer 30 including the crystal dislocations 31 at a higher density than the density of the crystal dislocations 11 in the channel layer 10 is thereby grown.

The pits 80 provided in the barrier layer 30 may be provided only in the region where the source electrode 50 is to be formed out of the regions where the source electrode 50 and the drain electrode 60 are to be formed. This causes the protrusions 51 to be provided only in the source electrode 50 out of the source electrode 50 and the drain electrode 60 and may reduce the contact resistance of the source electrode 50, suppress excessive concentration of an electrical field directly below the gate electrode 40 or the like, and improve the withstand voltage of the semiconductor device 1.

### Second Embodiment

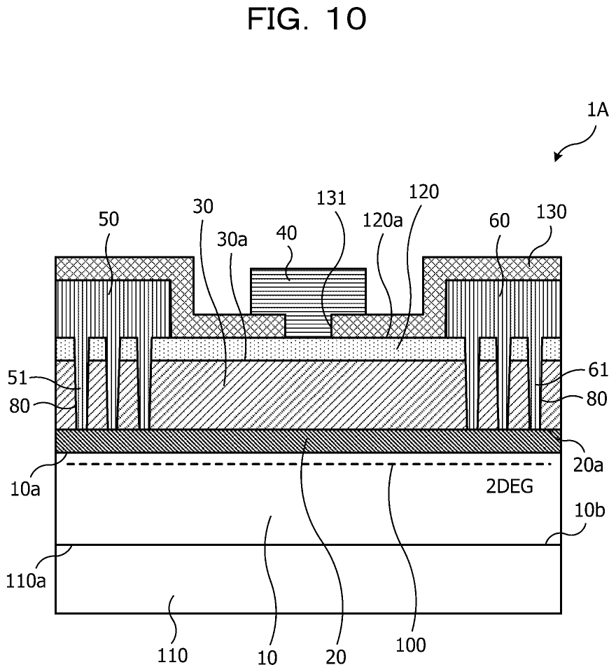

FIG. 10 is a diagram for explaining an example of a semiconductor device according to a second embodiment. FIG. 10 schematically illustrates a main portion cross-sectional diagram of the example of the semiconductor device.

The semiconductor device 1A illustrated in FIG. 10 is an example of the HEMT. The semiconductor device 1A includes an underlying substrate 110, a channel layer 10, a spacer layer 20, a barrier layer 30, a cap layer 120, a gate electrode 40, a source electrode 50, a drain electrode 60, and a passivation film 130. The semiconductor device 1A uses the channel layer 10, the spacer layer 20, the barrier layer 30, the gate electrode 40, the source electrode 50, and the drain electrode 60 similar to those in the semiconductor device 1 (FIGS. 8A and 8B) described in the above-mentioned first embodiment.

In the semiconductor device 1A, a substrate made of the same material as the channel layer 10 is used as the underlying substrate 110 of the channel layer 10. When a nitride semiconductor containing Ga is used for the channel layer 10, a substrate including the nitride semiconductor containing Ga (also referred to as a third nitride semiconductor) is used as the underlying substrate 110 arranged on the surface 10b side of the channel layer 10. For example, when GaN is used for the channel layer 10, a GaN substrate is used as the underlying substrate 110. The channel layer 10 is provided on a surface 110a side of the underlying substrate 110 such as the GaN substrate. The surface 110a of the underlying substrate 110 is, for example, a (0001) surface (c-surface, III-polar surface). The spacer layer 20 is provided on the surface 10a side of the channel layer 10, the barrier layer 30 is provided on the surface 20a side of the spacer layer 20, and the cap layer 120 is provided on the surface 30a side of the barrier layer 30.

The cap layer 120 includes a nitride semiconductor containing Ga (also referred to as a sixth nitride semiconductor). For example, GaN is used for the cap layer 120. The cap layer 120 has a function of protecting the barrier layer 30. The cap layer 120 includes crystal dislocations. A density of the crystal dislocations (also referred to as a crystal dislocation density (fourth crystal dislocation density)) in the cap layer 120 is relatively high, by reflecting the density of the crystal dislocations in the barrier layer 30 under the cap layer 120. The gate electrode 40, the source electrode 50, and the drain electrode 60 are provided on a surface 120a side of the cap layer 120 opposite to the barrier layer 30 side. The surface 120a of the cap layer 120 is, for example, a (0001) surface (c-surface, III-polar surface).

In the semiconductor device 1A, multiple pits 80 (also referred to as recesses) penetrating the cap layer 120 and extending into the barrier layer 30 are provided in regions of the cap layer 120 and the barrier layer 30, respectively, where the source electrode 50 and the drain electrode 60 are formed. The source electrode 50 is partially provided in the pits 80 provided in the cap layer 120 and the barrier layer 30, and the source electrode 50 having the multiple protrusions 51 is formed. The drain electrode 60 is partially provided in the pits 80 provided in the cap layer 120 and the barrier layer 30, and the drain electrode 60 having the multiple protrusions 61 is formed.

For example, the protrusions 51 of the source electrode 50, the protrusions 61 of the drain electrode 60, and the pits 80 in the barrier layer 30 in which the protrusions 51 and 61 are provided are formed to penetrate the cap layer 120, extend into the barrier layer 30, penetrate the barrier layer 30, and reach the spacer layer 20. Alternatively, the protrusions 51, the protrusions 61, and the pits 80 may penetrate the cap layer 120, extend into the barrier layer 30, and end in the middle of the barrier layer 30 in the thickness direction. Each of the protrusions 51, the protrusions 61, and the pits 80 is formed such that the distance between a lower end thereof and the 2DEG 100 is equal to or smaller than a distance at which electron tunneling is possible.

The passivation film 130 is provided to cover the cap layer 120, the source electrode 50, and the drain electrode 60. The passivation film 130 has an opening 131 leading to the cap layer 120. The gate electrode 40 is provided at a position of the opening 131 of the passivation film 130. For example, any of various insulating materials such as an oxide, a nitride, and an oxynitride is used for the passivation film 130. For example, silicon nitride (SiN) is used for the passivation film 130.

In the semiconductor device 1A, the densities of the crystal dislocations in the barrier layer 30 and the cap layer 120 are higher than the densities of the crystal dislocations in the channel layer 10 and the spacer layer 20. The pit assist etching is performed on the cap layer 120 and the barrier layer 30 including the crystal dislocations at relatively high densities. Accordingly, the case where the number of the pits 80 formed by etching in the cap layer 120 and the barrier layer 30 is small depending on the relatively low densities of the crystal dislocations in the channel layer 10 and the spacer layer 20 is suppressed. Suppressing the case where the number of the pits 80 in the cap layer 120 and the barrier layer 30 is small suppresses the case where the number of the protrusions 51 of the source electrode 50 and the protrusions 61 of the drain electrode 60 formed in the pits 80 is small. This reduces the contact resistance of the source electrode 50 and the drain electrode 60, and suppresses the case where the contact resistance reduction effect decreases due to a small number of the protrusions 51 and the protrusions 61 in the source electrode 51 and the drain electrode 60 (pits 80 in the cap layer 120 and the barrier layer 30). In the semiconductor device 1A, reducing the contact resistance of the source electrode 50 and the drain electrode 60 suppresses an increase in the resistance of the electron transport path formed between the source electrode 50 and the drain electrode 60 via the channel layer 10 and an increase in the on-resistance.

In the semiconductor device 1A, the density of the crystal dislocations in the channel layer 10 is lower than the density of the crystal dislocations in the barrier layer 30. In the semiconductor device 1A, using the channel layer 10 with a relatively low density of the crystal dislocations suppresses scattering or trapping of electrons, current collapse, a leakage current, or the like.

According to the above-mentioned configuration, there is achieved the high-performance semiconductor device 1A that has a low contact resistance and a low on-resistance and in which a leakage current or the like may be suppressed.

An example of a method for manufacturing the semiconductor device 1A having the above-mentioned configuration is described.

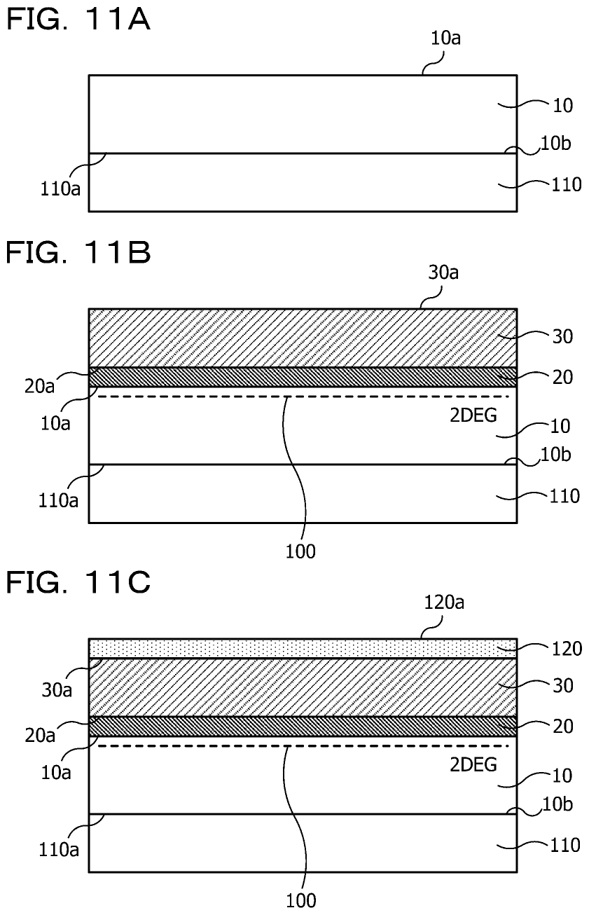

FIGS. 11A to 14B are diagrams for explaining the example of the method for manufacturing the semiconductor device according to the second embodiment. FIGS. 11A to 11C, 12A, 12B, 13A, 13B, 14A, and 14B each schematically illustrate a main portion cross-sectional diagram in a corresponding step of the manufacturing of the semiconductor device.

First, the underlying substrate 110 as illustrated in FIG. 11A is prepared. For example, a GaN substrate is prepared as the underlying substrate 110. As illustrated in FIG. 11A, the channel layer 10 is formed on the surface 110a ((0001) surface) side of the prepared underlying substrate 110. The channel layer 10 is grown over the surface 110a of the underlying substrate 110 by using the MOVPE method. For example, GaN is grown as the channel layer 10. The surface 10b of the channel layer 10 on the underlying substrate 110 side is a (000-1) surface, and the surface 10a on the opposite side to the surface 10b is a (0001) surface. The thickness of the channel layer 10 is set to, for example, 3 μm. Crystal dislocations are formed in the channel layer 10 at a density reflecting the density of the crystal dislocations included in the underlying substrate 110.

Next, as illustrated in FIG. 11B, the spacer layer 20 is formed on the surface 10a ((0001) surface) side of the channel layer 10. The spacer layer 20 is grown over the surface 10a of the channel layer 10 by using the MOVPE method. For example, AlN or AlGaN is grown as the spacer layer 20. In one example, AlₓGa₁₋ₓN (0.40≤x≤1.0) is grown as the spacer layer 20. The thickness of the spacer layer 20 is set to, for example, 2 nm. Crystal dislocations are formed in the spacer layer 20 at a density reflecting the density of the crystal dislocations included in the channel layer 10.

As illustrated in FIG. 11B, the barrier layer 30 is formed on the surface 20a ((0001) surface) side of the spacer layer 20. The barrier layer 30 is grown over the surface 20a of the spacer layer 20 by using the MOVPE method. For example, AlN, AlGaN, InAlN or InAlGaN is grown as the barrier layer 30. In one example, In_{y}Al₇Ga_{1-y-z}N (0≤y≤0.20, 0.10≤z≤1.0) is grown as the barrier layer 30. The thickness of the barrier layer 30 is set to, for example, 6 nm. The growth condition of the barrier layer 30 is appropriately adjusted with respect to the growth condition of the channel layer 10 and the spacer layer 20 such that crystal dislocations are formed at a predetermined density. For example, the channel layer 10 and the spacer layer 20 (underlying layer) are grown under a growth condition where the density of the crystal dislocations in each of the channel layer 10 and the spacer layer 20 becomes about the same as the density of the crystal dislocations in the case where the barrier layer 30 is grown at temperature higher than 850° C., based on the knowledge described in above-mentioned FIG. 9. On the surface 20a side of the spacer layer 20 grown under the aforementioned growth condition, the barrier layer 30 is grown under the growth condition of 850° C. or lower in the nitrogen atmosphere. The barrier layer 30 including the crystal dislocations at a higher density than the densities of the crystal dislocations in the channel layer 10 and the spacer layer 20 is thereby grown.

As illustrated in FIG. 11B, growing the spacer layer 20 and the barrier layer 30 on the surface 10a side of the channel layer 10 causes the 2DEG 100 to be generated in a portion of the channel layer 10 near a junction interface with the spacer layer 20.

Next, as illustrated in FIG. 11C, the cap layer 120 is formed on the surface 30a ((0001) surface) side of the barrier layer 30. The cap layer 120 is grown over the surface 30a of the barrier layer 30 by using the MOVPE method. For example, GaN is grown as the cap layer 120. The thickness of the cap layer 120 is set to, for example, 2 nm. Crystal dislocations are formed in the cap layer 120 at a density reflecting the density of the crystal dislocations included in the barrier layer 30. A growth condition for growing the cap layer 120 does not have to be the same as the growth condition for growing the barrier layer 30.

A mixed gas of ammonia (NH₃) and tri-methyl-gallium (TMGa), which is a Ga source, is used for the growth of GaN in the growth of each layer using the MOVPE method. A mixed gas of TMGa, NH₃, and tri-methyl-aluminum (TMAl), which is an Al source, is used for the growth of AlGaN. A mixed gas of TMAl and NH₃ is used for the growth of AlN. A mixed gas of TMAl, TMGa, NH₃, and tri-methyl-indium (TMIn), which is an In source, is used for the growth of InAlGaN. A mixed gas of TMIn, TMAl, and NH₃ is used for the growth of InAlN. Supply and stop (switching) of TMGa, TMAl, and TMIn and the flow rates thereof (mixing ratios with other raw materials) during the supply are set as appropriate depending on the nitride semiconductor to be grown. A pressure condition in the growth is in a range from about 1 kPa to about 100 kPa. A temperature condition in the growth is in a range from about 700° C. to about 1200° C. and is a temperature condition where the crystal dislocation densities in the channel layer 10 and the spacer layer 20 become lower than the crystal dislocation densities in the barrier layer 30 and the cap layer 120.

For example, after the formation of the nitride semiconductor laminate structure including the channel layer 10, the spacer layer 20, the barrier layer 30, and the cap layer 120 as illustrated in FIG. 11C, a mask (not illustrated) having an opening in a region where an element separation region is to be formed is formed by using a photolithography technique. The element separation region (not illustrated) is then formed in a predetermined region of the nitride semiconductor laminate structure by dry etching using a chlorine-based gas or by ion implantation of argon (Ar) or the like. After the formation of the element separation region, the mask is removed.

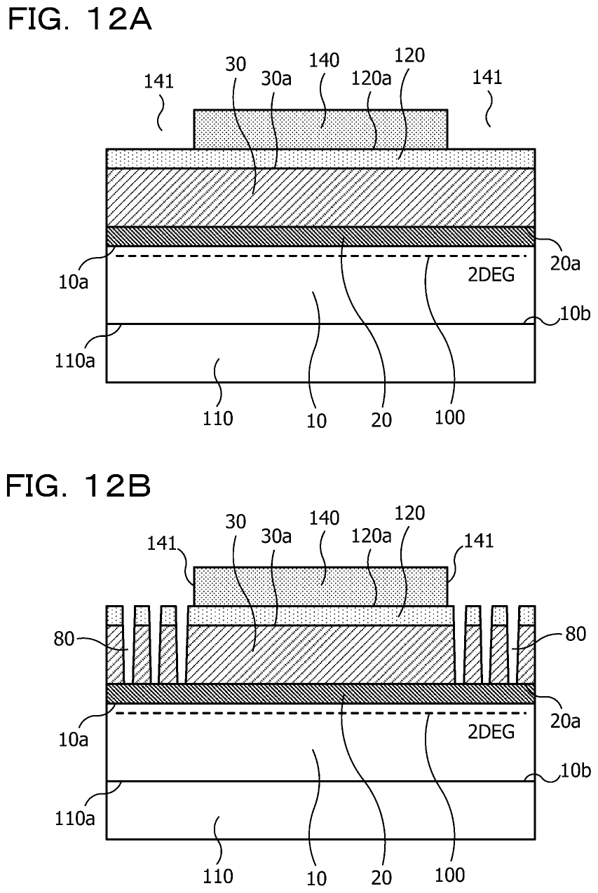

Next, as illustrated in FIG. 12A, a surface protection film 140 having openings 141 in the regions where the source electrode 50 and the drain electrode 60 are to be formed as described later is formed on the surface 120a side of the cap layer 120 in the nitride semiconductor laminate structure. For example, any of various insulating materials such as oxides, nitrides, and oxynitrides each containing at least one of Si, Al, hafnium (Hf), zirconium (Zr), titanium (Ti), tantalum (Ta), and tungsten (W) is used for the surface protection film 140. For example, SiN is used for the surface protection film 140. For example, a plasma chemical vapor deposition (CVD) method is used to form the surface protection film 140. Alternatively, an atomic layer deposition (ALD) method, a sputtering method, or the like may be used to form the surface protection film 140. The surface protection film 140 having the openings 141 is obtained as follows. For example, a material of the surface protection film 140 is formed over the entire surface by using the plasma CVD method or the like and then the openings 141 are formed in the predetermined regions by using the photolithography technique and the dry etching using the chlorine-based or fluorine-based gas.

As illustrated in FIG. 12B, the pit assist etching is then performed on the cap layer 120 exposed through the openings 141 of the surface protection film 140 and the barrier layer 30 under the cap layer 120 to form the pits 80. Etching proceeds by originating from the crystal dislocations in the cap layer 120 that are formed by reflecting the crystal dislocations in the barrier layer 30, and the pits 80 are formed in the cap layer 120 and the barrier layer 30. The pits 80 are formed by, for example, wet etching. Tetra-methyl-ammonium hydroxide (TMAH), potassium hydroxide, sodium hydroxide, sulfuric acid, hydrogen-peroxide water, or a mixed solution containing two or more of these substances is used as a chemical liquid for the wet etching in the formation of the pits 80. Each of the pits 80 is formed in a tapered shape in which the width of the pit 80 is large on the surface 120a side of the cap layer 120 and becomes smaller toward the inside of the barrier layer 30.

In the formation of the pits 80 by the wet etching, the temperature or the stirring rate of the chemical liquid may be adjusted as appropriate to change the shape or the etching rate of the pits 80. The pits 80 may be formed by plasma etching using a chlorine-based gas, instead of the wet etching. After the formation of the pits 80, the surface protection film 140 is removed.

Adjusting the growth condition of the barrier layer 30 in which the pits 80 are to be formed causes the crystal dislocations to be included in the barrier layer 30 at a relatively higher density than those in the channel layer 10 and the spacer layer 20. The crystal dislocations are included in the cap layer 120 at a relatively high density, by reflecting the crystal dislocations in the barrier layer 30. The pits 80 are formed by the pit assist etching in the cap layer 120 and the barrier layer 30 in which the crystal dislocations are included at relatively high densities as described above. The case where the number of the pits 80 formed by etching in the cap layer 120 and the barrier layer 30 is small depending on the relatively low densities of the crystal dislocations in the channel layer 10 and the spacer layer 20 is thus suppressed.

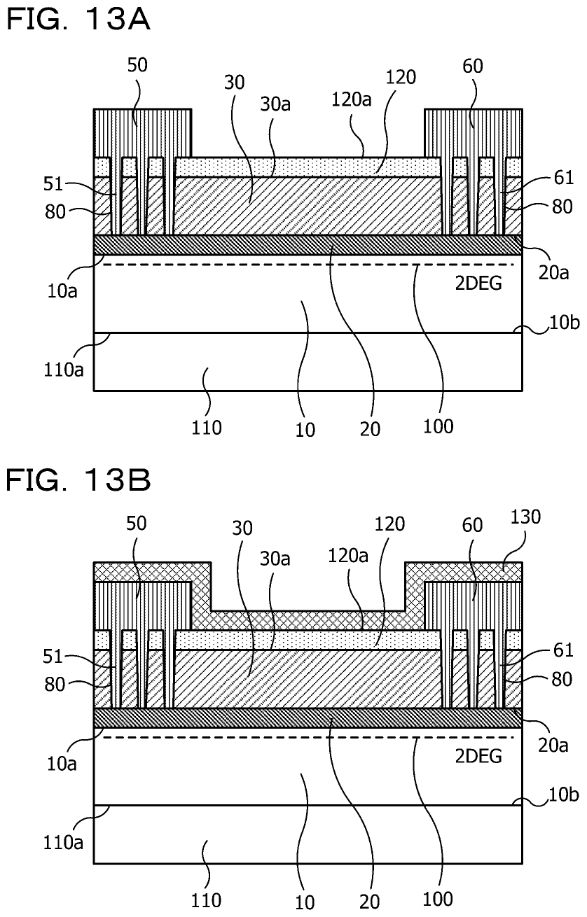

Next, as illustrated in FIG. 13A, the source electrode 50 and the drain electrode 60 are formed in the regions of the cap layer 120 where the pits 80 are formed. In this case, first, an electrode metal is formed in the regions where the source electrode 50 and the drain electrode 60 are to be formed, by using a photolithography technique, a vapor deposition technique, and a lift-off technique. For example, a laminate of Ta having a thickness of 20 nm and Al having a thickness of 200 nm is formed as the electrode metal. The electrode metal is formed over the surface 120a of the cap layer 120 and is also formed to enter the pits 80 formed in the cap layer 120 and the barrier layer 30. After the formation of the electrode metal, heat treatment is performed at 400° C. or higher and 1000° C. or lower, for example, at 550° C. in a nitrogen atmosphere to establish an ohmic contact of the electrode metal. This processing forms the source electrode 50 and the drain electrode 60 as illustrated in FIG. 13A, for example, the source electrode 50 and the drain electrode 60 that each partially enter the pits 80 and in which the group of protrusions 51 and the group of protrusions 61 are formed, respectively.

As described above, the case where the number of the pits 80 formed in the cap layer 120 and the barrier layer 30 is small is suppressed. Accordingly, the case where the number of the protrusions 51 of the source electrode 50 formed in the pits 80 and the number of the protrusions 61 of the drain electrode 60 formed in the pits 80 are small is suppressed. This reduces the contact resistance of the source electrode 50 and the drain electrode 60, and suppresses the case where the contact resistance reduction effect decreases due to a small number of the protrusions 51 and the protrusions 61 in the source electrode 51 and the drain electrode 60 (pits 80 in the cap layer 120 and the barrier layer 30).

Next, as illustrated in FIG. 13B, the passivation film 130 is formed to cover the cap layer 120, the source electrode 50, and the drain electrode 60. For example, the passivation film 130 made of SiN or the like having a thickness of 2 nm or more and 500 nm or less, for example, a thickness of 100 nm is formed by using the plasma CVD method. An ALD method, a sputtering method, or the like may be used to form the passivation film 130.

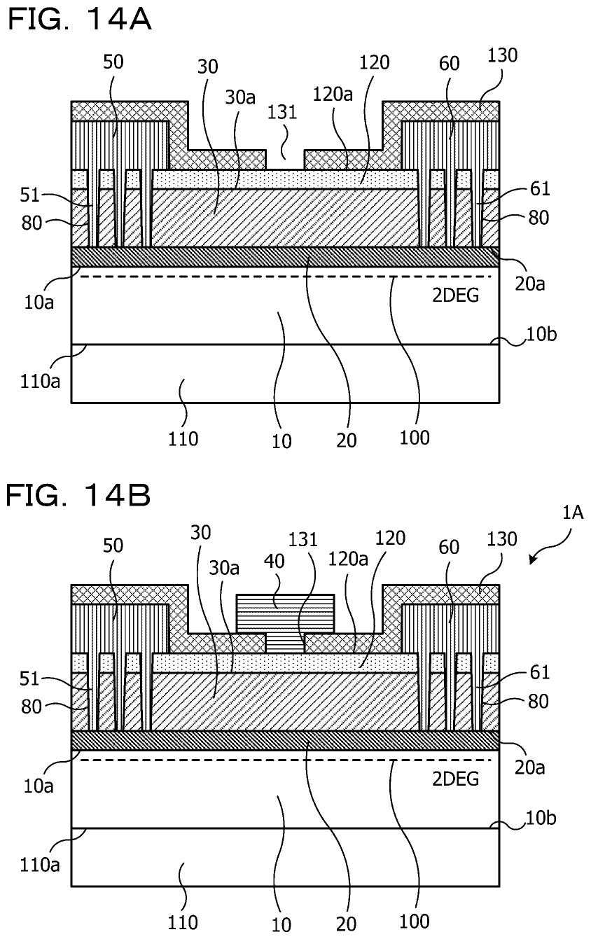

Next, as illustrated in FIG. 14A, the passivation film 130 in a region where the gate electrode 40 is to be formed is removed, and the opening 131 leading to the cap layer 120 is formed. In this case, first, a mask (not illustrated) having an opening in the region where the gate electrode 40 is to be formed is formed by using the photolithography technique, and dry etching is performed. The passivation film 130 exposed through the opening of the mask is removed by this etching, and the opening 131 of the passivation film 130 is formed. The etching of the passivation film 130 is performed by, for example, dry etching using a fluorine-based or chlorine-based gas. Alternatively, the passivation film 130 may be etched by wet etching using hydrofluoric acid, buffered hydrofluoric acid, or the like. After the etching of the passivation film 130, the mask is removed.

Next, as illustrated in FIG. 14B, the gate electrode 40 is formed at the position of the opening 131 of the passivation film 130. In this case, an electrode metal is formed at the position of the opening 131 of the passivation film 130 by using the photolithography technique, the vapor deposition technique, and the lift-off technique. For example, a laminate of nickel (Ni) having a thickness of 30 nm and gold (Au) having a thickness of 400 nm is formed as the electrode metal. The electrode metal is formed over the upper surface of the passivation film 130 and is also formed to enter the opening 131. The gate electrode 40 that functions as a Schottky electrode is thereby formed.

The semiconductor device 1A as illustrated in FIG. 14B (and FIG. 10 described above) is manufactured by the steps described above. As described above, in the semiconductor device 1A, each of the layers are formed such that the densities of the crystal dislocations in the channel layer 10 and the spacer layer 20 are relatively low and the densities of the crystal dislocations in the cap layer 120 and the barrier layer 30 are relatively high. This suppresses the case where the number of the pits 80 formed by the pit assist etching in the cap layer 120 and the barrier layer 30 is small depending on the relatively low densities of the crystal dislocations in the channel layer 10 and the spacer layer 20. Accordingly, the case where the number of the protrusions 51 of the source electrode 50 and the protrusions 61 of the drain electrode 60 formed in the pits 80 is small is suppressed. Suppressing the case where the number of the protrusions 51 of the source electrode 50 and the protrusions 61 of the drain electrode 60 is small as described above reduces the contact resistance of the source electrode 50 and the drain electrode 60 and reduces the on-resistance.

The cap layer 120 and the barrier layer 30 are formed to have relatively-high densities of the crystal dislocations to suppress the case where the number of the pits 80 is small, while the channel layer 10 and the spacer layer 20 are formed to have relatively-low densities of the crystal dislocations. In the semiconductor device 1A, using the channel layer 10 with a relatively low density of the crystal dislocations suppresses scattering or trapping of electrons, current collapse, a leakage current, or the like.

According to the above-mentioned manufacturing method, there is manufactured the high-performance semiconductor device 1A that has a low contact resistance and a low on-resistance and in which a leakage current or the like may be suppressed. Note that, in the semiconductor device 1A (the same applies to a semiconductor device 1B according to a third embodiment to be described later), types of metals and layer structures of the gate electrode 40, the source electrode 50, and the drain electrode 60 are not limited to the examples described above, and methods of forming them are not limited to the examples described above. Each of the gate electrode 40, the source electrode 50, and the drain electrode 60 may have a single-layer structure or a laminate structure. In the formation of the source electrode 50 and the drain electrode 60, the heat treatment as described above does not have to be performed as long as the ohmic contact is achieved by the formation of the electrode metals for these electrodes. In the formation of the gate electrode 40, heat treatment may be further performed after the formation of the electrode metal for the gate electrode 40.

Although the example in which the gate electrode 40 that functions as a Schottky electrode is provided in the semiconductor device 1A (the same applies to the semiconductor device 1B according to the third embodiment to be described later) is described herein, a gate insulating film using an oxide, a nitride, an oxynitride, or the like may be provided between the gate electrode 40 and the cap layer 120 to form a metal insulator semiconductor (MIS) type gate structure.

### Third Embodiment

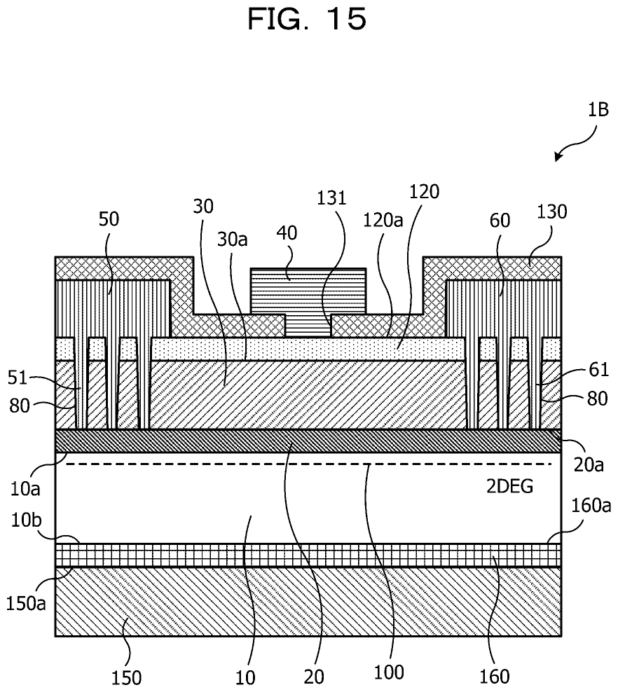

FIG. 15 is a diagram for explaining an example of a semiconductor device according to a third embodiment. FIG. 15 schematically illustrates a main portion cross-sectional diagram of the example of the semiconductor device.

The semiconductor device 1B illustrated in FIG. 15 is an example of the HEMT. The semiconductor device 1B has a configuration in which the channel layer 10 is provided on a surface 150a side of an underlying substrate 150 with a nucleation layer 160 interposed between the underlying substrate 150 and the channel layer 10. The semiconductor device 1B is different from the semiconductor device 1A described in the above-mentioned second embodiment in that the semiconductor device 1B has such a configuration.

In the semiconductor device 1B, a substrate made of a material different from the channel layer 10 is used as the underlying substrate 150. For example, when GaN is used for the channel layer 10, a semi-insulating SiC substrate is used as the underlying substrate 150 arranged on the surface 10b side of the channel layer 10. The nucleation layer 160 is provided on the surface 150a side of the underlying substrate 150 such as the semi-insulating SiC substrate. The surface 150a of the underlying substrate 150 is, for example, a (0001) surface (c-surface). The nucleation layer 160 includes a nitride semiconductor (also referred to as a fourth nitride semiconductor) containing Al. For example, AlN is used for the nucleation layer 160. The channel layer 10 is provided on a surface 160a side of the nucleation layer 160 opposite to the underlying substrate 150 side. The surface 160a of the nucleation layer 160 is, for example, a (0001) surface (c-surface, III-polar surface).

In the semiconductor device 1B, the spacer layer 20 is provided on the surface 10a side of the channel layer 10 provided over the underlying substrate 150 with the nucleation layer 160 interposed between the underlying substrate 150 and the channel layer 10, and the barrier layer 30 is provided on the surface 20a side of the spacer layer 20, as in the above-mentioned semiconductor device 1A. The cap layer 120 is provided on the surface 30a side of the barrier layer 30. The pits 80 are provided in the cap layer 120 and the barrier layer 30, and the source electrode 50 and the drain electrode 60 that partially enter the pits 80 and in which the protrusions 51 and the protrusions 61 are formed are provided, respectively. The passivation film 130 that covers the cap layer 120, the source electrode 50, and the drain electrode 60 is further provided, and the gate electrode 40 is provided at the position of the opening 131 of the passivation film 130.

In the semiconductor device 1B having the above-mentioned configuration, the densities of the crystal dislocations in the barrier layer 30 and the cap layer 120 are higher than the densities of the crystal dislocations in the channel layer 10 and the spacer layer 20 as in the above-mentioned semiconductor device 1A. Thus, the case where the number of the pits 80 formed by the pit assist etching in the cap layer 120 and the barrier layer 30 is small depending on the relatively low densities of the crystal dislocations in the channel layer 10 and the spacer layer 20 is suppressed. Accordingly, the case where the number of the protrusions 51 of the source electrode 50 and the protrusions 61 of the drain electrode 60 formed in the pits 80 is small is suppressed. The contact resistance of the source electrode 50 and the drain electrode 60 is thereby reduced, and the on-resistance is reduced.

In the semiconductor device 1B, the density of the crystal dislocations in the channel layer 10 is lower than the density of the crystal dislocations in the barrier layer 30. In the semiconductor device 1B, using the channel layer 10 with a relatively low density of the crystal dislocations suppresses scattering or trapping of electrons, current collapse, a leakage current, or the like.

According to the above-mentioned configuration, there is achieved the high-performance semiconductor device 1B that has a low contact resistance and a low on-resistance and in which a leakage current or the like may be suppressed.

An example of a method for manufacturing the semiconductor device 1B having the above-mentioned configuration is described.

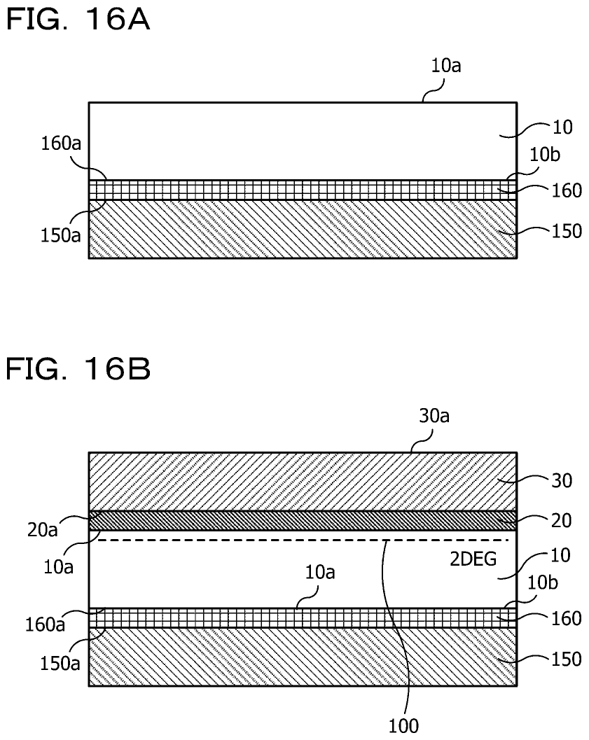

FIGS. 16A and 16B are diagrams for explaining the example of the method for manufacturing the semiconductor device according to the third embodiment. FIGS. 16A and 16B each schematically illustrate a main portion cross-sectional diagram in a corresponding step of the manufacturing of the semiconductor device.

First, the underlying substrate 150 as illustrated in FIG. 16A is prepared. For example, a semi-insulating SiC substrate is prepared as the underlying substrate 150. As illustrated in FIG. 16A, the nucleation layer 160 is formed on the surface 150a ((0001) surface) side of the prepared underlying substrate 150. The nucleation layer 160 is grown over the surface 150a of the underlying substrate 150 by using the MOVPE method. For example, AlN is grown as the nucleation layer 160. The thickness of the nucleation layer 160 is set to, for example, 100 nm. Crystal dislocations are formed in the nucleation layer 160 at a density reflecting the density of the crystal dislocations included in the underlying substrate 150.

As illustrated in FIG. 16A, the channel layer 10 is formed on the surface 160a ((0001) surface) side of the formed nucleation layer 160. The channel layer 10 is grown over the surface 160a of the nucleation layer 160 by using the MOVPE method. For example, GaN is grown as the channel layer 10. The surface 10b of the channel layer 10 on the underlying substrate 150 and nucleation layer 160 side is a (000-1) surface (N-polar surface), and the surface 10a on the opposite side to the surface 10b is a (0001) surface (III-polar surface). The thickness of the channel layer 10 is set to, for example, 3 μm. Crystal dislocations are formed in the channel layer 10 at a density reflecting the densities of the crystal dislocations included in the underlying substrate 150 and the nucleation layer 160. The channel layer 10 grown over the underlying substrate 150 using the semi-insulating SiC substrate with the nucleation layer 160 interposed between the underlying substrate 150 and the channel layer 10 may include the crystal dislocations at a higher density than that of the channel layer 10 grown over the underlying substrate 110 using the GaN substrate as described in the above-mentioned second embodiment.

Next, as illustrated in FIG. 16B, the spacer layer 20 is formed on the surface 10a ((0001) surface) side of the channel layer 10. The spacer layer 20 is grown over the surface 10a of the channel layer 10 by using the MOVPE method. For example, AlN or AlGaN is grown as the spacer layer 20. In one example, AlₓGa₁₋ₓN (0.40≤x≤1.0) is grown as the spacer layer 20. The thickness of the spacer layer 20 is set to, for example, 2 nm. Crystal dislocations are formed in the spacer layer 20 at a density reflecting the density of the crystal dislocations included in the channel layer 10.

As illustrated in FIG. 16B, the barrier layer 30 is formed on the surface 20a ((0001) surface) side of the spacer layer 20. The barrier layer 30 is grown over the surface 20a of the spacer layer 20 by using the MOVPE method. For example, AlN, AlGaN, InAlN or InAlGaN is grown as the barrier layer 30. In one example, In_{y}Al_{z}Ga_{1-y-z}N (0≤y≤0.20, 0.10≤z≤1.0) is grown as the barrier layer 30. The thickness of the barrier layer 30 is set to, for example, 6 nm. The growth condition of the barrier layer 30 is appropriately adjusted with respect to the growth condition of the channel layer 10 and the spacer layer 20 such that crystal dislocations are formed at a predetermined density. For example, the channel layer 10 and the spacer layer 20 (underlying layer) are grown under a growth condition where the density of the crystal dislocations in each of the channel layer 10 and the spacer layer 20 becomes about the same as the density of the crystal dislocations in the case where the barrier layer 30 is grown at temperature higher than 850° C., based on the knowledge described in above-mentioned FIG. 9. On the surface 20a side of the spacer layer 20 grown under the aforementioned growth condition, the barrier layer 30 is grown under the growth condition of 850° C. or lower in the nitrogen atmosphere. The barrier layer 30 including the crystal dislocations at a higher density than the densities of the crystal dislocations in the channel layer 10 and the spacer layer 20 is thereby grown.

As illustrated in FIG. 16B, growing the spacer layer 20 and the barrier layer 30 on the surface 10a side of the channel layer 10 causes a 2DEG 100 to be generated in a portion of the channel layer 10 near the junction interface with the spacer layer 20.

After the formation of the barrier layer 30, each of the steps is performed according to the example as illustrated in FIGS. 11C, 12A, 12B, 13A, 13B, 14A, and 14B in the above-mentioned second embodiment. The semiconductor device 1B as illustrated in above-mentioned FIG. 15 is thus manufactured.

As described above, in the semiconductor device 1B, each of the layers is formed such that the densities of crystal dislocations in the channel layer 10 and the spacer layer 20 are relatively low and the densities of crystal dislocations in the cap layer 120 and the barrier layer 30 are relatively high. This suppresses the case where the number of the pits 80 formed by the pit assist etching in the cap layer 120 and the barrier layer 30 is small depending on the relatively low densities of the crystal dislocations in the channel layer 10 and the spacer layer 20. Accordingly, the case where the number of the protrusions 51 of the source electrode 50 and the protrusions 61 of the drain electrode 60 formed in the pits 80 is small is suppressed. Suppressing the case where the number of the protrusions 51 of the source electrode 50 and the protrusions 61 of the drain electrode 60 is small as described above reduces the contact resistance of the source electrode 50 and the drain electrode 60 and reduces the on-resistance.

The cap layer 120 and the barrier layer 30 are formed to have relatively-high densities of the crystal dislocations to suppress the case where the number of the pits 80 is small, while the channel layer 10 and the spacer layer 20 are formed to have relatively-low densities of the crystal dislocations. In the semiconductor device 1B, using the channel layer 10 with a relatively low density of the crystal dislocations suppresses scattering or trapping of electrons, current collapse, a leakage current, or the like.

According to the above-mentioned manufacturing method, there is manufactured the high-performance semiconductor device 1B that has a low contact resistance and a low on-resistance and in which a leakage current or the like may be suppressed. Although the example in which the semi-insulating SiC substrate is used as the underlying substrate 150 is described herein, a conductive SiC substrate, a sapphire substrate, a GaN substrate, a Si substrate, a diamond substrate, or the like may be used as the underlying substrate 150.

Note that, in the semiconductor devices 1A and 1B described in the above-mentioned second and third embodiments, the barrier layer 30 may be directly joined over the channel layer 10 without provision of the spacer layer 20 made of AlN or AlGaN.

The pits 80 provided in the cap layer 120 and the barrier layer 30 may be provided only in the region where the source electrode 50 is formed out of the regions where the source electrode 50 and the drain electrode 60 are formed. This causes the protrusions 51 to be provided only in the source electrode 50 out of the source electrode 50 and the drain electrode 60 and may reduce the contact resistance of the source electrode 50, suppress excessive concentration of an electrical field directly below the gate electrode 40 or the like, and improve the withstand voltage of the semiconductor devices 1A and 1B.

### Fourth Embodiment

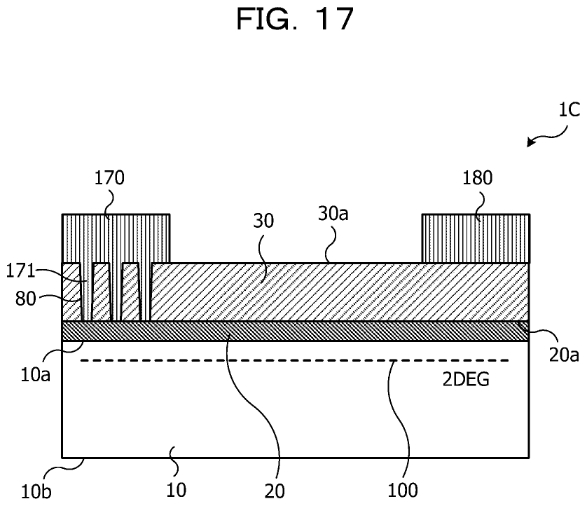

FIG. 17 is a diagram for explaining an example of a semiconductor device according to a fourth embodiment. FIG. 17 schematically illustrates a main portion cross-sectional diagram of the example of the semiconductor device.

The semiconductor device 1C illustrated in FIG. 17 is an example of a Schottky barrier diode (SBD). The semiconductor device 1C includes a channel layer 10, a spacer layer 20, a barrier layer 30, a cathode electrode 170 (ohmic electrode), and an anode electrode 180 (Schottky electrode). The semiconductor device 1C uses the channel layer 10, the spacer layer 20, and the barrier layer 30 similar to those in the semiconductor device 1 (FIGS. 8A and 8B) described in the above-mentioned first embodiment. A predetermined metal is used for each of the cathode electrode 170 and the anode electrode 180.

In the semiconductor device 1C, the cathode electrode 170 and the anode electrode 180 are provided on the surface 30a side of the barrier layer 30 to be spaced apart from each other, the barrier layer 30 provided on the surface 10a side of the channel layer 10. The pits 80 are formed by the pit assist etching according to the example described above, in the barrier layer 30 in a region of where the cathode electrode 170 is formed, and the cathode electrode 170 that partially enters the pits 80 and in which protrusions 171 are formed is formed on the surface 30a side of the barrier layer 30. Note that the underlying substrate 110 or a set of the underlying substrate 150 and the nucleation layer 160 as described above may be provided on the surface 10b side of the channel layer 10.

In the semiconductor device 1C, the protrusions 171 are provided only in the cathode electrode 170 that functions as the ohmic electrode out of the cathode electrode 170 and the anode electrode 180, and the contact resistance of the cathode electrode 170 is reduced. This achieves the high-performance semiconductor device 1C configured to function as the SBD that has high electron transport efficiency and excellent conducting characteristics when a forward bias is applied and that has high withstand voltage and excellent non-conducting characteristics when a reverse bias is applied.

According to the above-mentioned configuration, the semiconductor device 1C having low contact resistance and high performance is achieved.

First to fourth embodiments have been described above. The semiconductor devices 1, 1A, 1B, 1C, and the like having the configurations described in the first to fourth embodiments may be applied to various electronic devices. As an example, description is given below of the cases where the semiconductor devices having the configurations as described above are applied to a semiconductor package, a power factor correction circuit, a power supply device, and an amplifier.

### Fifth Embodiment

An example of applying the semiconductor device having the configuration as described above to a semiconductor package is described as a fifth embodiment.

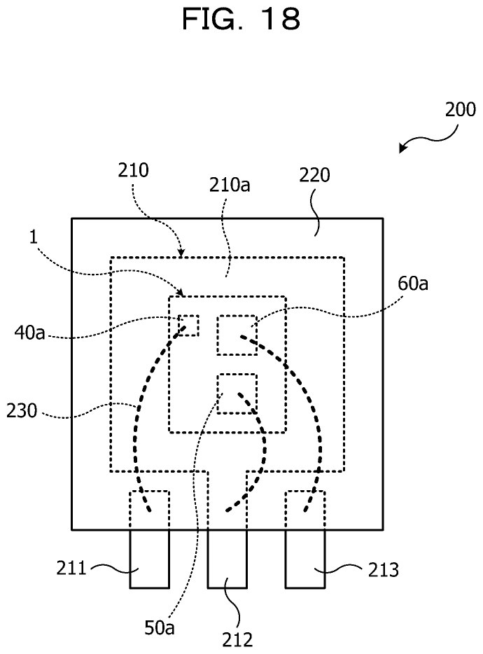

FIG. 18 is a diagram for explaining an example of the semiconductor package according to the fifth embodiment. FIG. 18 schematically illustrates a main portion plan view of the example of the semiconductor package. The semiconductor package 200 illustrated in FIG. 18 is an example of a discrete package. For example, the semiconductor package 200 includes the semiconductor device 1 (FIGS. 8A and 8B) as described in the above-mentioned first embodiment, a lead frame 210 where the semiconductor device 1 is mounted, and a resin 220 in which the semiconductor device 1 and the lead frame 210 are encapsulated.

For example, the semiconductor device 1 is mounted over a die pad 210a of the lead frame 210 by using a die-attach material or the like (not illustrated). A pad 40a coupled to the above-mentioned gate electrode 40, a pad 50a coupled to the source electrode 50, and a pad 60a coupled to the drain electrode 60 are provided in the semiconductor device 1. The pad 40a, the pad 50a, and the pad 60a are coupled to a gate lead 211, a source lead 212, and a drain lead 213 of the lead frame 210, respectively, by using wires 230 made of Au, Al or the like. The lead frame 210, the semiconductor device 1 mounted over the lead frame 210, and the wires 230 coupling the lead frame 210 and the semiconductor device 1 to each other are encapsulated in the resin 220 such that each of the gate lead 211, the source lead 212, and the drain lead 213 is partially exposed.

An external coupling electrode coupled to the source electrode 50 may be provided over a surface of the semiconductor device 1 on the opposite side to a surface where the pad 40a coupled to the gate electrode 40 and the pad 60a coupled to the drain electrode 60 are provided. A conductive joining material such as solder may be used to couple the external coupling electrode to the die pad 210a leading to the source lead 212.

For example, the semiconductor device 1 as described in the above-mentioned first embodiment is used, and the semiconductor package 200 having such a configuration is obtained. As described above, in the semiconductor device 1 that functions as the HEMT, the barrier layer 30 having a higher crystal dislocation density than the channel layer 10 is provided on the surface 10a side of the channel layer 10. This suppresses the case where the number of the pits 80 formed by the pit assist etching and the number of the electrode portions such as the protrusions 51 of the source electrode 50 formed in the pits 80 are small depending on the crystal dislocation density of the channel layer 10. As a result, the contact resistance of the ohmic electrodes such as the source electrode 50 is reduced, and the on-resistance is reduced. Using the channel layer 10 having a relatively low crystal dislocation density suppresses a leakage current or the like. The semiconductor device 1 that has low contact resistance and high performance is achieved. The high-performance semiconductor package 200 is achieved by using such a semiconductor device 1.

Although the semiconductor device 1 is given as an example in this section, the semiconductor package may be similarly obtained by using the other semiconductor devices 1A, 1B, and the like that function as the HEMT. The semiconductor package may also be obtained by using the semiconductor device 1C or the like that functions as the SBD. As described above, in the semiconductor device 1C or the like that functions as the SBD, the performance of the SBD in the case where forward and reverse biases are applied is improved. The high-performance semiconductor package is achieved by using such a semiconductor device 1C or the like.

### Sixth Embodiment

An example of applying the semiconductor device having the configuration as described above to a power factor correction circuit is described as a sixth embodiment.

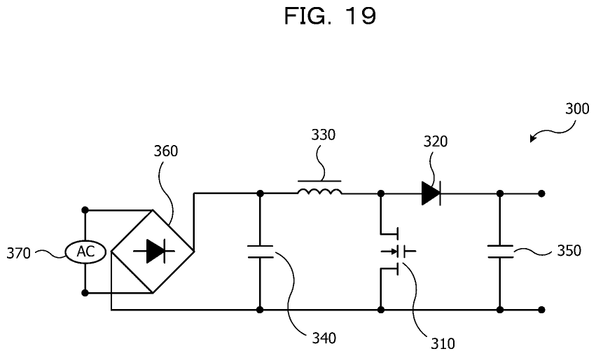

FIG. 19 is a diagram for explaining an example of the power factor correction circuit according to the sixth embodiment. FIG. 19 illustrates an equivalent circuit diagram of the example of the power factor correction circuit. The power-factor correction (PFC) circuit 300 illustrated in FIG. 19 includes a switch element 310, a diode 320, a choke coil 330, a capacitor 340, a capacitor 350, a diode bridge 360, and an alternating current (AC) power supply 370.

In the PFC circuit 300, a drain electrode of the switch element 310 is coupled to an anode terminal of the diode 320 and one terminal of the choke coil 330. A source electrode of the switch element 310 is coupled to one terminal of the capacitor 340 and one terminal of the capacitor 350. Another terminal of the capacitor 340 is coupled to another terminal of the choke coil 330. Another terminal of the capacitor 350 is coupled to a cathode terminal of the diode 320. A gate driver is coupled to a gate electrode of the switch element 310. The alternating current power supply 370 is coupled between both terminals of the capacitor 340 via the diode bridge 360, and a direct current (DC) power supply is extracted from between both terminals of the capacitor 350.

For example, the above-mentioned semiconductor device 1, 1A, 1B, or the like that functions as the HEMT is used as the switch element 310 of the PFC circuit 300 having such a configuration. As described above, in the semiconductor device 1, 1A, 1B, or the like that functions as the HEMT, the barrier layer 30 having a higher crystal dislocation density than the channel layer 10 is provided on the surface 10a side of the channel layer 10. This suppresses the case where the number of the pits 80 formed by the pit assist etching and the number of the electrode portions such as the protrusions 51 of the source electrode 50 formed in the pits 80 are small depending on the crystal dislocation density of the channel layer 10. As a result, the contact resistance of the ohmic electrodes such as the source electrode 50 is reduced, and the on-resistance is reduced. Using the channel layer 10 having a relatively low crystal dislocation density suppresses a leakage current or the like. The semiconductor device 1, 1A, 1B, or the like that has low contact resistance and high performance is achieved. The high-performance PFC circuit 300 is achieved by using such a semiconductor device 1, 1A, 1B, or the like.

The semiconductor device 1C or the like that functions as the SBD may be used as the diode 320 and the diode bridge 360 of the PFC circuit 300. As described above, in the semiconductor device 1C or the like, the performance of the SBD in the case where forward and reverse biases are applied is improved. The high-performance PFC circuit 300 is achieved by using such a semiconductor device 1C or the like.

### Seventh Embodiment

An example of applying the semiconductor device having the configuration as described above to a power supply device is described as a seventh embodiment.

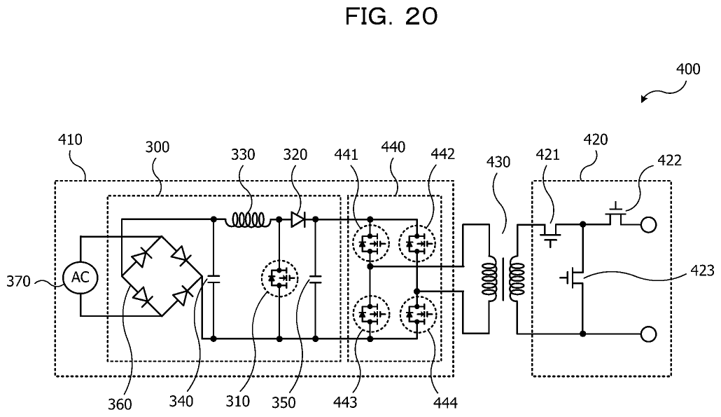

FIG. 20 is a diagram for explaining an example of the power supply device according to the seventh embodiment. FIG. 20 illustrates an equivalent circuit diagram of the example of the power supply device. The power supply device 400 illustrated in FIG. 20 includes a primary-side circuit 410, a secondary-side circuit 420, and a transformer 430 provided between the primary-side circuit 410 and the secondary-side circuit 420.

The primary-side circuit 410 includes the PFC circuit 300 as described in the above-mentioned sixth embodiment and an inverter circuit, for example, a full-bridge inverter circuit 440 coupled between both terminals of the capacitor 350 of the PFC circuit 300. The full-bridge inverter circuit 440 includes multiple (for example, four in this case) switch elements of a switch element 441, a switch element 442, a switch element 443, and a switch element 444.

The secondary-side circuit 420 includes multiple (for example, three in this case) switch elements of a switch element 421, a switch element 422, and a switch element 423. For example, the above-mentioned semiconductor device 1, 1A, 1B, or the like that functions as the HEMT is used as the switch element 310 of the PFC circuit 300 and the switch elements 441, 442, 443, and 444 of the full-bridge inverter circuit 440 included in the primary-side circuit 410 of the power supply device 400 having such a configuration. For example, a normal MIS type FET using Si is used as the switch elements 421, 422, and 423 in the secondary-side circuit 420 of the power supply device 400.

As described above, in the semiconductor device 1, 1A, 1B, or the like that functions as the HEMT, the barrier layer 30 having a higher crystal dislocation density than the channel layer 10 is provided on the surface 10a side of the channel layer 10. This suppresses the case where the number of the pits 80 formed by the pit assist etching and the number of the electrode portions such as the protrusions 51 of the source electrode 50 formed in the pits 80 are small depending on the crystal dislocation density of the channel layer 10. As a result, the contact resistance of the ohmic electrodes such as the source electrode 50 is reduced, and the on-resistance is reduced. Using the channel layer 10 having a relatively low crystal dislocation density suppresses a leakage current or the like. The semiconductor device 1, 1A, 1B, or the like that has low contact resistance and high performance is achieved. The high-performance power supply device 400 is achieved by using such a semiconductor device 1, 1A, 1B, or the like.

As described in the above-mentioned sixth embodiment, the semiconductor device 1C or the like that functions as the SBD may be used as the diode 320 and the diode bridge 360 of the PFC circuit 300 included in the primary-side circuit 410. The high-performance PFC circuit 300 is achieved by using such a semiconductor device 1C or the like. The high-performance power supply device 400 is achieved by using such a PFC circuit 300.

### Eighth Embodiment

An example of applying the semiconductor device having the configuration as described above to an amplifier is described as an eighth embodiment.

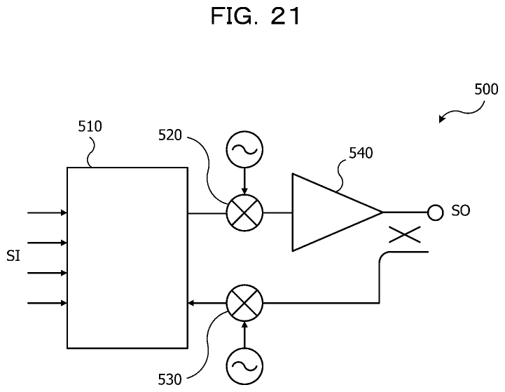

FIG. 21 is a diagram for explaining an example of the amplifier according to the eighth embodiment. FIG. 21 illustrates an equivalent circuit diagram of the example of the amplifier. The amplifier 500 illustrated in FIG. 21 includes a digital predistortion circuit 510, a mixer 520, a mixer 530, and a power amplifier 540.

The digital predistortion circuit 510 compensates for non-linear distortion of an input signal. The mixer 520 mixes an alternating current signal and the input signal SI subjected to the non-linear distortion compensation. The power amplifier 540 amplifies a signal obtained by mixing the alternating current signal and the input signal SI. For example, in the amplifier 500, switching of a switch may cause an output signal SO to be mixed with an alternating current signal in the mixer 530 and to be transmitted to the digital predistortion circuit 510. The amplifier 500 may be used as a high-frequency amplifier or a high-output amplifier.

The above-mentioned semiconductor device 1, 1A, 1B, or the like that functions as the HEMT is used as the power amplifier 540 of the amplifier 500 having such a configuration. As described above, in the semiconductor device 1, 1A, 1B, or the like that functions as the HEMT, the barrier layer 30 having a higher crystal dislocation density than the channel layer 10 is provided on the surface 10a side of the channel layer 10. This suppresses the case where the number of the pits 80 formed by the pit assist etching and the number of the electrode portions such as the protrusions 51 of the source electrode 50 formed in the pits 80 are small depending on the crystal dislocation density of the channel layer 10. As a result, the contact resistance of the ohmic electrodes such as the source electrode 50 is reduced, and the on-resistance is reduced. Using the channel layer 10 having a relatively low crystal dislocation density suppresses a leakage current or the like. The semiconductor device 1, 1A, 1B, or the like that has low contact resistance and high performance is achieved. The high-performance amplifier 500 is achieved by using such a semiconductor device 1, 1A, 1B, or the like.

When a diode is used in the amplifier 500, the semiconductor device 1C or the like that functions as the SBD may be used as the diode. As described above, in the semiconductor device 1C or the like, the performance of the SBD in the case where forward and reverse biases are applied is improved. The high-performance amplifier 500 is achieved by using such a semiconductor device 1C or the like.

Various electronic devices (such as the semiconductor package 200, the PFC circuit 300, the power supply device 400, and the amplifier 500 described in the above-mentioned fifth to eighth embodiments) to which the above-mentioned semiconductor devices 1, 1A, 1B, 1C, or the like is applied may be mounted in various electronic apparatuses and electronic devices. For example, the electronic devices may be mounted in various electronic apparatuses and electronic devices such as a computer (a personal computer, a super computer, a server, or the like), a smartphone, a mobile phone, a tablet terminal, a sensor, a camera, an audio device, a measurement apparatus, an inspection apparatus, a manufacturing apparatus, a transmitter, a receiver, and a radar apparatus.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a channel layer configured to include a first nitride semiconductor containing gallium (Ga) and a first crystal dislocation density; and
a barrier layer provided over a first surface side of the channel layer, and configured to include a second nitride semiconductor containing aluminum (Al) and a second crystal dislocation density,
wherein the second crystal dislocation density is larger than the first crystal dislocation density.

2. The semiconductor device according to claim 1, wherein the first crystal dislocation density is 1×10⁷/cm² or smaller, and the second crystal dislocation density is 1×10⁸/cm² or larger.

3. The semiconductor device according to claim 1, further comprising:
a substrate provided over a second surface side of the channel layer opposite to the first surface side, and configured to include a third nitride semiconductor containing Ga.

4. The semiconductor device according to claim 1, further comprising:
a substrate provided over a second surface side of the channel layer opposite to the first surface side; and
a nucleation layer provided between the channel layer and the substrate, and configured to include a fourth nitride semiconductor containing Al.

5. The semiconductor device according to claim 1, further comprising:
an electrode provided over an opposite side of the barrier layer to the channel layer, and configured to include a plurality of protrusions extending to an inside of the barrier layer.

6. The semiconductor device according to claim 5, wherein the plurality of protrusions each includes a tapered shape in which a width of the protrusion becomes smaller toward the inside of the barrier layer.

7. The semiconductor device according to claim 1, further comprising:
a spacer layer provided between the channel layer and the barrier layer, and configured to include a fifth nitride semiconductor containing Al and a third crystal dislocation density,
wherein the third crystal dislocation density is smaller than the second crystal dislocation density of the barrier layer.

8. The semiconductor device according to claim 1, further comprising:
a cap layer provided over an opposite side of the barrier layer to the channel layer, and configured to include a sixth nitride semiconductor containing Ga and a fourth crystal dislocation density,
wherein the fourth crystal dislocation density is larger than the first crystal dislocation density of the channel layer.

9. The semiconductor device according to claim 1, wherein the first surface of the channel layer is a (0001) surface.

10. A method for manufacturing semiconductor device, the method comprising:
forming a channel layer configured to include a first nitride semiconductor containing gallium (Ga) and a first crystal dislocation density; and
forming a barrier layer provided over a first surface side of the channel layer, and configured to include a second nitride semiconductor containing aluminum (Al) and a second crystal dislocation density,
wherein the second crystal dislocation density is larger than the first crystal dislocation density.

11. The method according to claim 10, wherein the forming the barrier layer includes growing the second nitride semiconductor at temperature of 850° C. or lower in a nitrogen atmosphere.

12. The method according to claim 10, further comprising:
preparing a substrate including a third nitride semiconductor containing Ga, wherein the forming the channel layer includes forming the channel layer over the substrate, the channel layer including the first surface over an opposite side to the substrate, and
the forming the barrier layer includes forming the barrier layer over the first surface of the channel layer over the opposite side to the substrate.

13. The method according to claim 10, further comprising:
preparing a substrate in which a nucleation layer is formed, the nucleation layer including a fourth nitride semiconductor containing Al, wherein
the forming the channel layer includes forming the channel layer over the nucleation layer of the substrate, the channel layer including the first surface over an opposite side to the nucleation layer, and
the forming the barrier layer includes forming the barrier layer over the first surface of the channel layer over the opposite side to the nucleation layer and the substrate.

14. The method according to claim 10, further comprising:
forming a plurality of pits extending to an inside of the barrier layer in a portion of the barrier layer after the forming the barrier layer.

15. The method according to claim 14, further comprising:
forming an electrode configured to include a plurality of protrusions formed respectively in the plurality of pits, over an opposite side of the barrier layer to the channel layer.

16. The method according to claim 10, further comprising:
forming a spacer layer over the first surface side of the channel layer after the forming the channel layer, the spacer layer including a third crystal dislocation density and a fifth nitride semiconductor containing Al, wherein
the third crystal dislocation density is smaller than the second crystal dislocation density of the barrier layer, and
the forming the barrier layer includes forming the barrier layer over an opposite side of the spacer layer to the channel layer.

17. The method according to claim 10, further comprising:
forming a cap layer on over opposite side of the barrier layer to the channel layer after the forming the barrier layer, the cap layer including a fourth crystal dislocation density and a sixth nitride semiconductor containing Ga,
wherein the fourth crystal dislocation density is larger than the first crystal dislocation density of the channel layer.

18. An electronic device comprising:
a channel layer configured to include a first nitride semiconductor containing gallium (Ga) and a first crystal dislocation density; and
a barrier layer provided over a first surface side of the channel layer, and configured to include a second nitride semiconductor containing aluminum (Al) and a second crystal dislocation density,
wherein the second crystal dislocation density is larger than the first crystal dislocation density.
